(19) United States
(12) Patent Application Publication
(10) Pub. No.: US 2018/0299737 A1
(43) Pub. Date: Oct. 18, 2018

(54) LIQUID CRYSTAL DISPLAY PANEL, AND LIQUID CRYSTAL DISPLAY DEVICE

(71) Applicant: Sharp Kabushiki Kaisha, Sakai City, Osaka (JP)

(72) Inventors: Fumikazu SHIMOSHIKIRYOH, Sakai City (JP); Takehisa YOSHIDA, Sakai City (JP)

(73) Assignee: Sharp Kabushiki Kaisha, Sakai City, Osaka (JP)

(21) Appl. No.: 15/766,383

(22) PCT Filed: Jan. 19, 2017
(86) PCT No.: PCT/JP2017/001688

§ 371 Date: Apr. 6, 2018

(30) Foreign Application Priority Data
Jan. 20, 2016 (JP) 2016-008842

(51) Int. Cl. G02F 1/1362; G02F 1/1368; G02F 1/1345; G02F 1/1335; H01L 27/12

(52) U.S. Cl. CPC G02F 1/136286; G02F 1/1368; G02F 1/13454; G02F 1/133512; G02F 2201/40; H01L 27/1255; G02F 1/136213; G02F 2203/30; H01L 27/124

(57) ABSTRACT

A liquid crystal display panel (100A) has a display region (21), a picture-frame region (22) around the display region (21), plural pixels that are disposed like a matrix with m rows and n columns in the display region (21), plural TFTs (18a) and (18b), plural gate bus lines (12), plural source bus lines (14a) and (14b), and plural vertical bus lines (17) that extend in a column direction. The display region (21) has at least one first display region (21a) in which the plural vertical bus lines (17) are formed and at least one second display region (21b) in which the plural vertical bus lines (17) are not formed, and the at least one second display region (21b) includes K or more contiguous pixel columns in a case where an integer that is greater than 1/20 of n is set as K.

### TECHNICAL FIELD

The present invention relates to a liquid crystal display panel and a liquid crystal display device, particularly to a large-sized liquid crystal display panel and a liquid crystal display device for use for a high-definition television and so forth.

### BACKGROUND ART

The applicant manufactures and sells liquid crystal display panels that have a multi-pixel structure. Referring to FIG. 20, a description will be made about an example of a TFT substrate that is used for a liquid crystal display panel that has a multi-pixel structure. FIG. 20 is a plan diagram that schematically illustrates a TFT substrate 10X which is used for a liquid crystal display panel which has a multi-pixel structure.

The TFT substrate 10X has a multi-pixel structure, and each pixel P has two sub-pixels SPa and SPb. The two sub-pixels SPa and SPb are disposed along the column direction. The two sub-pixels SPa and SPb may exhibit mutually different gray scales (luminances). In accordance with the source signal voltage (gray scale signal voltage) that is input to the pixel P, one sub-pixel SPa exhibits a high gray scale, the other sub-pixel SPb exhibits a low gray scale with respect to the gray scale to be displayed by the pixel P, and the pixel P as a whole exhibits the gray scale in accordance with the input source signal voltage. The multi-pixel structure is particularly preferably used for a liquid crystal display panel of a vertical alignment mode and may improve the viewing angle dependence of the gamma characteristic thereof. A structure and a driving method of a liquid crystal display panel that has a multi-pixel structure are disclosed in PTL 1 by the present applicant, for example. The entire disclosed contents of PTL 1 will be incorporated herein by reference.

The TFT substrate 10X has two sub-pixel electrodes (a first sub-pixel electrode 11a and a second sub-pixel electrode 11b) that correspond to the two sub-pixels (the first sub-pixel SPa and the second sub-pixel SPb). The two sub-pixel electrodes 11a and 11b that configure one pixel P may collectively be referred to as pixel electrode. The two sub-pixel electrodes 11a and 11b are supplied with the source signal voltage from a common source bus line 14a or 14b via two TFTs 18a and 18b that are connected with a common gate bus line 12, for example. Because the ON-OFF control of the two TFTs 18a and 18b may of course be performed at the same timing, the two TFTs 18a and 18b do not necessarily have to be connected with the common gate bus line 12. The same applies to the source bus line 14a or 14b. However, because the increase in the numbers of gate bus lines and/or source bus lines becomes a factor of lowering of the aperture ratio, the two TFTs that respectively correspond to the two sub-pixels SPa and SPb which configure one pixel P are preferably connected with the common gate bus line 12 or the common source bus line 14a or 14b.

The first sub-pixel SPa has a first auxiliary capacitance, and the second sub-pixel SPb has a second auxiliary capacitance. Mutually different auxiliary capacitance voltages are supplied from an auxiliary capacitance bus line CSa that is connected with the first auxiliary capacitance of the first sub-pixel SPa and an auxiliary capacitance bus line CSb that is connected with the second auxiliary capacitance of the second sub-pixel SPb, and effective voltages that are applied to a liquid crystal layer of the first sub-pixel SPa and a liquid crystal layer of the second sub-pixel SPb are thereby made different. Here, the auxiliary capacitance bus lines CSa and CSb are electrically independent from the gate bus line 12. Note that in the whole liquid crystal display panel that has the TFT substrate 10X, for example, 12 kinds of auxiliary capacitance wiring that are mutually electrically independent as the auxiliary capacitance bus lines CSa and CSb are provided, and 12 kinds of auxiliary capacitance voltages are supplied to the respectively corresponding auxiliary capacitance electrodes (which may be referred to as “auxiliary capacitance counter electrode”) of sub-pixels in accordance with the phases of the auxiliary capacitance voltages. For example, the 12 kinds of auxiliary capacitance voltages are supplied from 12 auxiliary capacitance trunk lines that are electrically independent to the respective pieces of auxiliary capacitance wiring.

In an ordinary liquid crystal display panel, because the same voltage as a liquid crystal capacitance is applied to the auxiliary capacitance, the same voltage as the pixel electrode is supplied to one of a pair of electrodes that configure the auxiliary capacitance, and the same voltage (common voltage) as a common electrode (counter electrode) is supplied to the other electrode. Differently, in the liquid crystal display panel that has a multi-pixel structure, mutually different oscillating voltages (voltages that oscillate within one vertical scanning period) are supplied from the above auxiliary capacitance bus lines CSa and CSb. The oscillating voltages are typically voltages whose phases are different by 180° between the auxiliary capacitance bus line CSa and the auxiliary capacitance bus line CSb.

The auxiliary capacitance wiring and the auxiliary capacitance electrode that is connected therewith are formed with the same metal layer as the gate bus line (referred to as gate metal layer), for example. A dielectric layer of the auxiliary capacitance is formed with a gate insulting layer, for example. An electrode that is formed on the dielectric layer on the auxiliary capacitance electrode is formed with the same conductive layer as the pixel electrode (sub-pixel electrode) or the same metal layer as the source bus line (source metal layer) and is electrically connected with a drain of the TFT or the pixel electrode (sub-pixel electrode).

In the liquid crystal display panel disclosed in PTL 1, the auxiliary capacitance trunk lines are arranged in picture-frame regions in the horizontal direction (left-right direction) of a display region. For example, the 12 auxiliary capacitance trunk lines are arranged in left and right picture-frame regions.

In consideration of the rise in needs for picture-frame narrowing, a liquid crystal display panel in which the left and right picture-frame regions of the display region are narrowed has been developed by providing auxiliary capacitance trunk lines that extend from a picture-frame region on an upper side of the display region into the display region in the column direction (PTL 2). Note that in PTL 2, an auxiliary capacitance trunk line that is formed in the picture-frame region on the upper side of the display region and extends in the row direction is referred to as “horizontal trunk wiring”, and an auxiliary capacitance trunk line that extends from the horizontal trunk wiring into the display region in the column direction is referred to as “branch wiring”.

In the liquid crystal display panel disclosed in PTL 2, the branch wiring is uniformly arranged throughout the whole display region. PTL 2 discloses that the branch wiring is arranged in each color display pixel, each of the color display pixels may thereby have the same configuration, and occurrence of display unevenness among each of the color display pixels may be inhibited. For example, PTL 2 discloses that as for an example where the color display pixel is configured with an R pixel, a G pixel, and a B pixel, any one of pixels of three primary colors may be selected or any two may be selected as the pixels in which the branch wiring is arranged. Further, PTL 2 discloses that in a case where the tinge of the color display pixel changes due to the arrangement of the branch wiring, adjustment may be performed by the color of a backlight. Note that in PTL 2, the color display pixel herein is referred to as “pixel”, and the pixel herein is referred to as “sub-pixel”.

### CITATION LIST

### Patent Literature

PTL 1: Japanese Unexamined Patent Application Publication No. 2005-189804 (Japanese Patent No. 4265788)

PTL 2: International Publication No. 2010/134439 Pamphlet

### SUMMARY OF INVENTION

### Technical Problem

The techniques disclosed in PTL 2 may achieve picture-frame narrowing. However, there is a problem that the aperture ratio lowers throughout a whole display region because branch wiring is arranged in each color display pixel throughout the whole display region.

An object of the present invention is to provide a liquid crystal display panel and a liquid crystal display device that have a narrow picture-frame and a high aperture ratio.

### Solution to Problem

A liquid crystal display panel according to an embodiment of the present invention includes: a display region; a picture-frame region around the display region; plural pixels that are disposed in the display region like a matrix with m rows and n columns (m and n are integers of 1000 or greater which are independent from each other); plural TFTs, each of the TFTs being connected with any of the plural pixels; plural gate bus lines that extend in a row direction, each of the plural gate bus lines being connected with at least one of the plural TFTs; plural source bus lines that extend in a column direction, each of the plural source bus lines being connected with at least one of the plural TFTs; and plural vertical bus lines that extend in the column direction. The display region has at least one first display region in which the plural vertical bus lines are formed and at least one second display region in which the plural vertical bus lines are not formed, and at least one second display region includes K or more contiguous pixel columns in a case where an integer that is greater than 1/20 of n is set as K.

In one embodiment, each of the plural pixels has a first sub-pixel and a second sub-pixel that exhibit mutually different luminances at least one gray scale, the liquid crystal display panel further includes plural auxiliary capacitance bus lines that extend in the row direction, each of the plural auxiliary capacitance bus lines being connected with an auxiliary capacitance that is provided to at least one of the first sub-pixel and the second sub-pixel which are provided to the plural pixels, and the plural vertical bus lines are plural vertical auxiliary capacitance trunk lines that are each connected with two or more of the plural auxiliary capacitance bus lines.

In one embodiment, the liquid crystal display panel further includes plural horizontal auxiliary capacitance trunk lines that are formed in the picture-frame region on an upper side or a lower side of the display region, in which each of the plural vertical auxiliary capacitance trunk lines is connected with any one of the plural horizontal auxiliary capacitance trunk lines.

In one embodiment, wiring that is electrically connected with any of the plural auxiliary capacitance bus lines is not formed in the picture-frame region of the display region in a horizontal direction.

In one embodiment, the liquid crystal display panel further includes gate drive circuits that supply a scanning signal to the plural gate bus lines, at least a portion of the gate drive circuits being formed in the display region, in which the plural vertical bus lines include a vertical bus line that is connected with the gate drive circuit.

In one embodiment, the at least one first display region is two first display regions that are provided at both ends of the display region in the horizontal direction.

In one embodiment, plural pixels that are included in the at least one first display region include a pixel with a lower aperture ratio than plural pixels that are included in the at least one second display region.

In one embodiment, the liquid crystal display panel further includes a black matrix that has plural light shielding columns which are arranged to perform light shielding among the plural pixels, in which plural first light shielding columns, which are arranged in the at least one first display region, among the plural light shielding columns, include a light shielding column with a larger width than plural second light shielding columns, which are arranged in the at least one second display region.

In one embodiment, a gradation process is carried out for a boundary region of the at least one second display region that is adjacent to the at least one first display region.

In one embodiment, the liquid crystal display panel further includes a black matrix that has plural light shielding columns which are arranged to perform light shielding among the plural pixels, in which the plural light shielding columns include plural first light shielding columns that are arranged in the at least one first display region and plural second light shielding columns that are arranged in the at least one second display region, and the plural second light shielding columns include two or more kinds of light shielding columns with mutually different widths.

In one embodiment, the two or more kinds of light shielding columns are disposed such that a width of the light shielding column becomes smaller as the light shielding column is positioned farther from the at least one first display region.

In one embodiment, the two or more kinds of light shielding columns include plural wide width light shielding columns and plural narrow width light shielding columns and are disposed such that a density of the narrow width light shielding columns becomes higher as the light shielding column is positioned farther from the at least one first display region.

In one embodiment, a width of each of the two or more kinds of light shielding columns is constant in the column direction.

In one embodiment, the two or more kinds of light shielding columns include light shielding columns that have plural wide width portions and plural narrow width portions and are disposed such that a ratio of the plural wide width portions that are included in the light shielding columns becomes lower as the light shielding column is positioned farther from the at least one first display region.

In one embodiment, the two or more kinds of light shielding columns include light shielding columns that have plural wide width portions and plural narrow width portions and are disposed such that the width of the plural wide width portions that are included in the light shielding columns becomes smaller as the light shielding column is positioned farther from the at least one first display region.

In one embodiment, the liquid crystal display panel further includes a black matrix that has plural light shielding columns which are arranged to perform light shielding among the plural pixels, in which the plural pixels configure plural color display pixels, each of the plural color display pixels includes three pixels that display mutually different colors, the plural pixels have plural unit regions that are disposed like a matrix with rows and columns, each of the plural unit regions includes the p×q (p and q are integers of 2 or greater to 1024 or less that are independent from each other) color display pixels, and the plural unit regions in the boundary region include light shielding columns that have plural wide width portions and plural narrow width portions and the unit region whose distance from the at least one first display region is longer has the light shielding column with a smaller area.

In one embodiment, in the boundary region, arrangement of the plural wide width portions and the plural narrow width portions in one unit region is different from arrangement of the plural wide width portions and the plural narrow width portions in an adjacent unit region to the unit region in the row direction.

In one embodiment, in the boundary region, arrangement of the plural wide width portions and the plural narrow width portions in one unit region is the same as arrangement of the plural wide width portions and the plural narrow width portions in an adjacent unit region to the unit region in the column direction.

In one embodiment, in the boundary region, arrangement of the plural wide width portions and the plural narrow width portions in one unit region is different from arrangement of the plural wide width portions and the plural narrow width portions in an adjacent unit region to the unit region in the column direction.

The liquid crystal display device according to an embodiment of the present invention includes the liquid crystal display panel according to any one of the above embodiments, and a backlight unit that emits light toward the liquid crystal display panel, in which the backlight unit has plural light sources, the plural light sources include at least one first light source that is arranged correspondingly to the at least one first display region and at least one second light source that is arranged correspondingly to the at least one second display region, and in one gray scale, the at least one first light source includes the first light source that emits light with higher intensity than intensity of light which is emitted by the at least one second light source in the one gray scale.

### Advantageous Effects of Invention

The embodiments of the present invention provide a liquid crystal display panel and a liquid crystal display device that have a narrow picture-frame and a high aperture ratio.

### BRIEF DESCRIPTION OF DRAWINGS

FIG. 1 is a schematic plan diagram of a liquid crystal display panel 100A according to a first embodiment of the present invention.

FIG. 2 is a schematic plan diagram of a TFT substrate 10A that is used for the liquid crystal display panel according to an embodiment of the present invention.

FIG. 3 is one example of a schematic cross-sectional diagram of the TFT substrate 10A along line 3A-3A′ in FIG. 2.

FIG. 4 is another example of the schematic cross-sectional diagram of the TFT substrate 10A along line 3A-3A′ in FIG. 2.

FIG. 5 is a schematic plan diagram for explaining a pixel region and an aperture ratio of a pixel of the TFT substrate 10A.

FIG. 6 is a schematic plan diagram of a TFT substrate 10B that is used for the liquid crystal display panel according to an embodiment of the present invention.

FIG. 7 is a schematic plan diagram for explaining the pixel region and the aperture ratio of the pixel of the TFT substrate 10B.

FIG. 8 is one example of a schematic cross-sectional diagram of the TFT substrate 10B along line 8A-8A′ in FIG. 6.

FIG. 9 is another example of the schematic cross-sectional diagram of the TFT substrate 10B along line 8A-8A′ in FIG. 6.

FIG. 10 is a schematic plan diagram of a liquid crystal display panel 100B according to a second embodiment of the present invention.

FIG. 11 is a schematic plan diagram of a liquid crystal display panel 100C according to a third embodiment of the present invention.

FIG. 12(a) is a schematic plan diagram of the liquid crystal display panel 100A, and FIG. 12(b) is a schematic diagram for explaining transmittance of a display region 21 of the liquid crystal display panel 100A.

FIG. 13(a) is a schematic plan diagram of a liquid crystal display panel 100D according to a fourth embodiment of the present invention, FIG. 13(b) is a schematic diagram for explaining the transmittance of the display region 21 of the liquid crystal display panel 100D, and FIG. 13(c) is a diagram that schematically illustrates one example of a gradation process.

FIG. 14(a) is a schematic diagram for explaining the transmittance of the liquid crystal display panel according to the fourth embodiment, for which the gradation process of FIG. 14(b) is carried out, and FIG. 14(b) is a diagram that schematically illustrates another example of the gradation process.

FIG. 15(a) is a schematic diagram for explaining the transmittance of the liquid crystal display panel according to the fourth embodiment, for which the gradation process of FIG. 15(b) or FIG. 15(c) is carried out, FIG. 15(b) is a diagram that schematically illustrates still another example of the gradation process, and FIG. 15(c) is a diagram that schematically illustrates yet another example of the gradation process.

FIG. 16(a) is a schematic diagram for explaining the transmittance of the liquid crystal display panel according to the fourth embodiment, for which the gradation process of FIG. 16(b) is carried out, and FIG. 16(b) is a diagram that schematically illustrates further another example of the gradation process.

FIG. 17 is a schematic diagram that illustrates a general configuration of a liquid crystal display panel to which an in-pixel gate driver monolithic (IPGDM) technology is applied.

FIG. 18 is a diagram that illustrates an equivalent circuit of a gate driver which is formed in a display region of the liquid crystal display panel to which the IPGDM technology is applied.

FIG. 19(a) is a schematic plan diagram of a TFT substrate 10Y that is used for the liquid crystal display panel to which the IPGDM technology is applied, and FIG. 19(b) is an enlarged diagram of a color display pixel of the TFT substrate 10Y.

FIG. 20 is a plan diagram that schematically illustrates a TFT substrate 10X which is used for a liquid crystal display panel in related art.

### DESCRIPTION OF EMBODIMENTS

Liquid crystal display panels according to embodiments of the present invention will be described hereinafter with reference to drawings. Note that the present invention is not limited to the embodiments that are exemplified in the following. In the following drawings, configuration elements that have substantially the same functions will be denoted by common reference characters, and descriptions thereof may not be made.

### First Embodiment

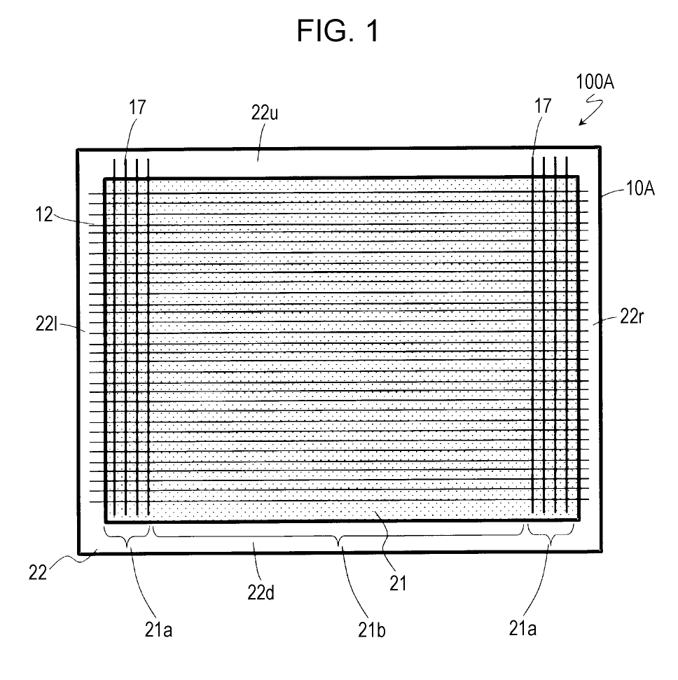

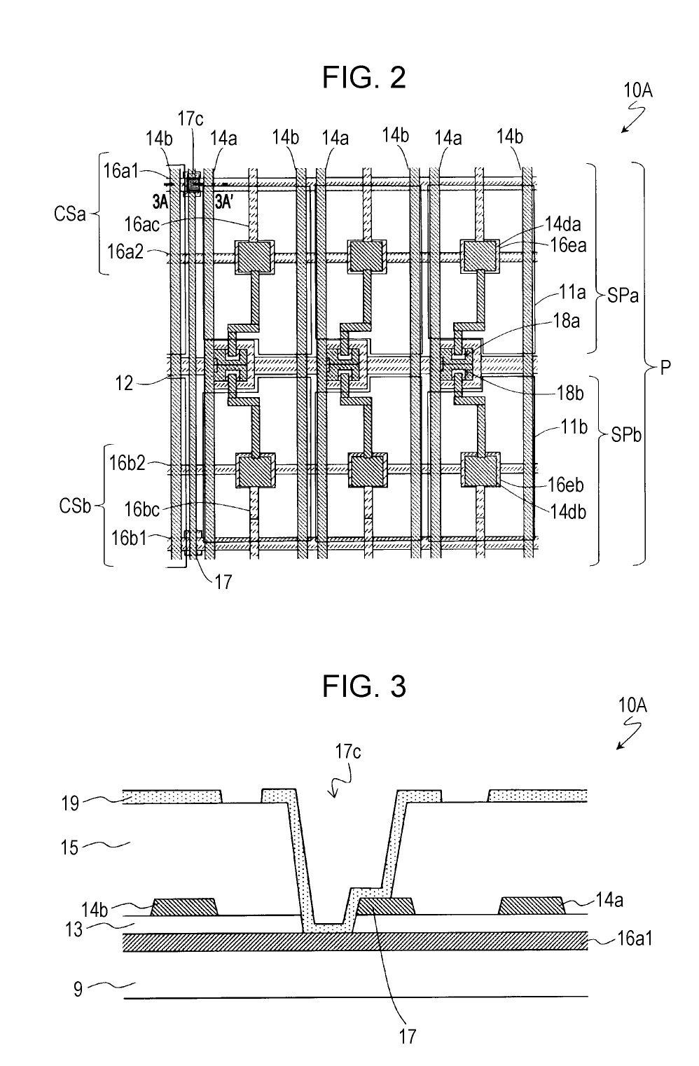

A liquid crystal display panel 100A according to a first embodiment of the present invention will be described with reference to FIG. 1 and FIG. 2. FIG. 1 is a schematic plan diagram of the liquid crystal display panel 100A according to the first embodiment of the present invention. FIG. 2 is a schematic plan diagram of a TFT substrate 10A that is used for the liquid crystal display panel 100A according to the first embodiment of the present invention.

The liquid crystal display panel 100A has the TFT substrate 10A, a counter substrate (not illustrated), and a liquid crystal layer (not illustrated) that is provided between those. The liquid crystal display panel 100A has a display region 21 and a picture-frame region 22 around the display region 21. In the region of the TFT substrate 10A that corresponds to the display region 21, pixel electrodes that are disposed like a matrix with m rows and n columns (m and n are integers of 1000 or greater that are independent from each other), TFTs whose drain electrodes are connected with the respective pixel electrodes, gate bus lines 12 that are connected with gate electrodes of the TFTs, and source bus lines 14a and 14b that are connected with source electrodes of the TFTs. The gate bus line 12 is supplied with a gate signal voltage (scanning signal voltage) from a gate driver (gate drive circuit), and the source bus lines 14a and 14b are supplied with a source signal voltage (display signal voltage) from a source driver (source drive circuit).

The liquid crystal display panel 100A has a multi-pixel structure. Each pixel P has two sub-pixels (a first sub-pixel SPa and a second sub-pixel SPb). The two sub-pixels SPa and SPb are disposed along the column direction. The two sub-pixels SPa and SPb may exhibit mutually different gray scales (luminances). In accordance with the source signal voltage (gray scale signal voltage) that is input to the pixel P, one sub-pixel SPa exhibits a high gray scale, the other sub-pixel SPb exhibits a low gray scale with respect to the gray scale to be displayed by the pixel P, and the pixel P as a whole exhibits the gray scale in accordance with the input source signal voltage.

The TFT substrate 10A has plural TFTs 18a and 18b. Each of the plural TFTs 18a and 18b is connected with any of the first sub-pixels SPa and the second sub-pixels SPb of the plural pixels. For example, the TFT 18a is connected with the first sub-pixel SPa, and the TFT 18b is connected with the second sub-pixel SPb.

The TFT substrate 10A has plural gate bus lines 12 that extend in the row direction. Each of the plural gate bus lines 12 is connected with at least one of the plural TFTs 18a and 18b.

The TFT substrate 10A has plural source bus lines 14a and 14b that extend in the column direction. Each of the plural source bus lines 14a and 14b is connected with at least one of the plural TFTs 18a and 18b.

The TFT substrate 10A has plural auxiliary capacitance bus lines CSa and CSb that extend in the row direction. Each of the auxiliary capacitance bus lines CSa and CSb is connected with an auxiliary capacitance that is provided to at least one of the first sub-pixel SPa and the second sub-pixel SPb which are provided to the plural pixels. For example, the auxiliary capacitance bus line CSa is connected with a first auxiliary capacitance provided to the first sub-pixel SPa, and the auxiliary capacitance bus line CSb is connected with a second auxiliary capacitance provided to the second sub-pixel SPb.

The TFT substrate 10A has plural vertical auxiliary capacitance trunk lines 17 that extend in the column direction. Each of the plural vertical auxiliary capacitance trunk lines 17 is connected with two or more of the plural auxiliary capacitance bus lines CSa and CSb.

The display region 21 has at least one first display region 21a in which the plural vertical auxiliary capacitance trunk lines 17 are formed and at least one second display region 21b in which the plural vertical auxiliary capacitance trunk lines 17 are not formed. At least one second display region 21b includes K or more contiguous pixel columns given that an integer that is greater than 1/20 of n is set as K. For example, K is 180.

The liquid crystal display panel 100A has the vertical auxiliary capacitance trunk lines 17 that are provided in the display region 21 and may thus achieve picture-frame narrowing. The liquid crystal display panel 100A has the vertical auxiliary capacitance trunk lines 17 only in the first display region 21a of the display region 21 but does not have the vertical auxiliary capacitance trunk lines 17 in the second display region 21b and may thus obtain a high aperture ratio. The liquid crystal display panel 100A has a narrow picture-frame and a high aperture ratio.

The first display region 21a is configured with a color display pixel that includes a pixel in which the vertical auxiliary capacitance trunk line 17 is formed in a pixel region, and the second display region 21b is configured with a color display pixel that does not include the pixel in which the vertical auxiliary capacitance trunk line 17 is formed in the pixel region. The pixel region will be described later with reference to FIG. 5. The color display pixel of the liquid crystal display panel 100A is configured with three pixels of an R pixel, a G pixel, and a B pixel that display three colors (primary color pixels). However, embodiments of the present invention are not limited to this, but one color display pixel may be configured with four pixels of the R pixel, the G pixel, the B pixel, and a Y pixel (yellow) that display four colors. The vertical auxiliary capacitance trunk line 17 may be provided only in the pixel region of the pixel of one certain color among the pixels that configure a color pixel region included in the first display region 21a, or the vertical auxiliary capacitance trunk line 17 may be provided only in the pixel region of the pixels of two certain colors.

In this embodiment, as illustrated in FIG. 1, two first display regions 21a are provided at both ends of the display region 21 in the horizontal direction. A central portion of the display region 21 in the horizontal direction is configured with the second display region 21b. The number of pixel columns included in the second display region 21b is 30% or more of the number of pixel columns included in the display region 21, for example. Because the second display region 21b as a main portion that is used for display in the display region 21 of the liquid crystal display panel 100A is configured with pixels that have a high aperture ratio, a high transmittance may be obtained. As the number of pixel columns provided to the first display region 21a becomes less, the aperture ratio of the liquid crystal display panel 100A may be improved more. Given that the number of vertical auxiliary capacitance trunk lines 17 that are electrically independent is L, the total number of pixel columns included in the first display region 21a is a minimum of L.

For example, in a 4K display panel, in a case where the number of pixel columns included in the second display region 21b is set to 30% of the number of pixel columns included in the display region 21 and the number of pixel columns included in each of two first display regions 21a is set to 35% of the number of pixel columns included in the display region 21, each of the first display regions 21a includes 1344 (=3840×0.35) color display pixel columns. In a case where the color display pixel is configured with the R pixel, the G pixel, and the B pixel of three colors, each of the first display regions 21a includes 4032 (=3840×0.35×3) pixel columns. Given that the number of vertical auxiliary capacitance trunk lines 17 that are electrically independent is L=12, the number of pixel columns included in each of the first display regions 21a is expressed as 336L (3840×0.35×3/12=336). An 8K display panel has twice pixel columns of the 4K display panel. Thus, in the 8K display panel, the number of pixel columns becomes a twice value of the above 4K display panel (for example, the number of pixel columns included in each of the first display region 21a is expressed as 672L).

A picture-frame region 22r on a right side of the display region 21 and a picture-frame region 221 on a left side of the display region 21 (both of those may collectively be referred to as picture-frame region 22 of the display region 21 in the horizontal direction) do not have an auxiliary capacitance trunk line, for example. That is, the picture-frame region 22r on the right side of the display region 21 and the picture-frame region 221 on the left side of the display region 21 do not have wiring that is electrically connected with either one of the auxiliary capacitance bus lines CSa and CSb. In the liquid crystal display panel 100A, particularly, the picture-frame regions 22 on the right and left sides of the display region 21 may be narrowed. Even in a case where the auxiliary capacitance trunk lines that are provided in the picture-frame region 22r on the right side of the display region 21 and the picture-frame region 221 on the left side of the display region 21 are not completely omitted, the vertical auxiliary capacitance trunk lines 17 are provided in the display region 21, the number of the auxiliary capacitance trunk lines that are provided in the picture-frame regions 22 may be lessened, and/or the thickness may be decreased. Accordingly, picture-frame narrowing may be achieved.

A picture-frame region 22u on an upper side of the display region 21 and a picture-frame region 22d on a lower side of the display region 21 do not have the auxiliary capacitance trunk line, for example. The picture-frame region 22u on the upper side of the display region 21 or the picture-frame region 22d on the lower side of the display region 21 may be provided with an auxiliary capacitance voltage control circuit that directly supplies an auxiliary capacitance voltage to the vertical auxiliary capacitance trunk lines 17, for example.

The liquid crystal display panel 100A may further have plural horizontal auxiliary capacitance trunk lines (not illustrated) that are formed in the picture-frame region 22u on the upper side of the display region 21 and the picture-frame region 22d on the lower side of the display region 21. Each of the plural vertical auxiliary capacitance trunk lines 17 is connected with any one of the plural horizontal auxiliary capacitance trunk lines. For example, the auxiliary capacitance voltage is supplied from the auxiliary capacitance voltage control circuit to the horizontal auxiliary capacitance trunk line, and the auxiliary capacitance voltage is supplied from the horizontal auxiliary capacitance trunk line to the vertical auxiliary capacitance trunk line 17.

A structure of the TFT substrate 10A will be described in detail with reference to FIG. 2. FIG. 2 is the schematic plan diagram of the TFT substrate 10A that is used for the liquid crystal display panel 100A and schematically illustrates the region that corresponds to the first display region 21a.

The TFT substrate 10A has two sub-pixel electrodes (a first sub-pixel electrode 11a and a second sub-pixel electrode 11b) that correspond to the two sub-pixels (the first sub-pixel SPa and the second sub-pixel SPb). The two sub-pixel electrodes 11a and 11b that configure one pixel P may collectively be referred to as pixel electrode. The two sub-pixel electrodes 11a and 11b are supplied with the source signal voltage from the common source bus line 14a or 14b via the two TFTs 18a and 18b that are connected with the common gate bus line 12, for example. Because the ON-OFF control of the two TFTs 18a and 18b may of course be performed at the same timing, the two TFTs 18a and 18b do not necessarily have to be connected with the common gate bus line 12. The same applies to the source bus line 14a or 14b. However, because the increase in the numbers of gate bus lines and/or source bus lines becomes a factor of lowering of the aperture ratio, the two TFTs that respectively correspond to the two sub-pixels SPa and SPb which configure one pixel P are preferably connected with the common gate bus line 12 or the common source bus line 14a or 14b.

Note that the liquid crystal display panel 100A exemplified here has a double source structure and respectively has one source bus line 14a and one source bus line 14b on both sides of plural pixels that are disposed along the column direction (which may be referred to as pixel column). In the drawing, the source bus line provided on the left side of the pixel will be expressed as source bus line 14a, and the source bus line provided on the right side of the pixel will be expressed as source bus line 14b. As exemplified later, the liquid crystal display panel according to an embodiment of the present invention does not necessarily have to have the double source structure.

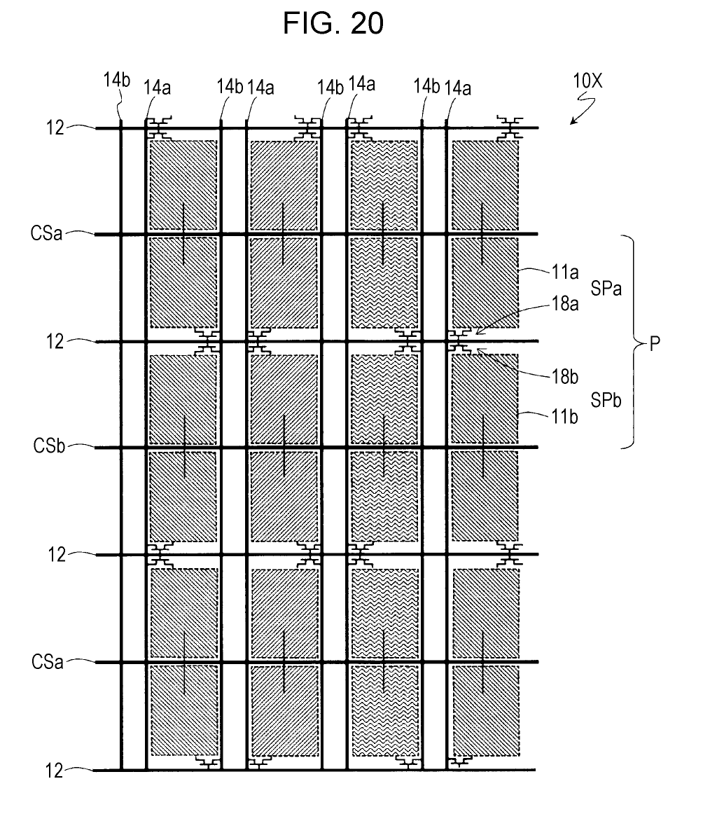

The liquid crystal display panel 100A that has the double source structure has a structure as illustrated in FIG. 20, for example. That is, as illustrated in FIG. 20, each of the pixels provided to the plural pixels that are disposed along the column direction (pixel column) is connected with any of the source bus lines 14a and 14b that are provided correspondingly to the pixel column. The mutually adjacent pixels in the column direction among the plural pixels disposed along the column direction are connected with mutually different source bus lines 14a and 14b. The sub-pixels SPa and SPb provided to a certain pixel P are connected with the same source bus line 14a or 14b.

The first sub-pixel SPa has the first auxiliary capacitance, and the second sub-pixel SPb has the second auxiliary capacitance. Mutually different auxiliary capacitance voltages are supplied from the auxiliary capacitance bus line CSa that is connected with the first auxiliary capacitance of the first sub-pixel SPa and the auxiliary capacitance bus line CSb that is connected with the second auxiliary capacitance of the second sub-pixel SPb, and effective voltages that are applied to the liquid crystal layer of the first sub-pixel SPa and the liquid crystal layer of the second sub-pixel SPb are thereby made different. In such a manner, in the liquid crystal display panel that has the multi-pixel structure, mutually different oscillating voltages (voltages that oscillate within one vertical scanning period) are supplied from the auxiliary capacitance bus lines CSa and CSb. The oscillating voltages are typically voltages whose phases are different by 180° between the auxiliary capacitance bus line CSa and the auxiliary capacitance bus line CSb. The auxiliary capacitance bus lines CSa and CSb are electrically independent from the gate bus line 12.

The auxiliary capacitance bus lines CSa and CSb are connected with any of the vertical auxiliary capacitance trunk lines 17 that are provided in the display region 21.

In the whole liquid crystal display panel 100A, for example, 12 kinds of vertical auxiliary capacitance trunk lines 17 that are mutually electrically independent as the auxiliary capacitance bus lines CSa and CSb are provided, and auxiliary capacitance voltages are supplied to the respectively corresponding auxiliary capacitance electrodes of the sub-pixels in accordance with the phases of the auxiliary capacitance voltages. Given that the number of vertical auxiliary capacitance trunk lines 17 that are electrically independent among the plural vertical auxiliary capacitance trunk lines 17 is L, for example, L kinds of auxiliary capacitance voltages are supplied from L vertical auxiliary capacitance trunk lines 17 to the respective auxiliary capacitance bus lines CSa and CSb.

The connection relationship between the auxiliary capacitance trunk lines and the respective auxiliary capacitance bus lines are disclosed in PTL 1 by the present applicant, for example. PTL 1 discloses that plural auxiliary capacitance trunk lines that are electrically independent are prepared, a different oscillating voltage is supplied to each of those, and the oscillating period of the auxiliary capacitance voltage may thereby be made longer. The connection form of the auxiliary capacitance trunk lines, which is disclosed in PTL 1, may be employed for the connection form between the vertical auxiliary capacitance trunk lines 17 and the auxiliary capacitance bus lines CSa and CSb. The entire disclosed contents of PTL 1 will be incorporated herein by reference.

The auxiliary capacitance bus lines CSa and CSb are electrically connected with the auxiliary capacitance electrodes of the auxiliary capacitances. For example, as illustrated in FIG. 2, the auxiliary capacitance bus line CSa is electrically connected with a first auxiliary capacitance electrode 16ea of the first auxiliary capacitance provided to the first sub-pixel SPa. The first auxiliary capacitance is formed with the first auxiliary capacitance electrode 16ea, an expansion portion 14da of drain lead-out wiring of the TFT 18a, which is opposed to the first auxiliary capacitance electrode 16ea across an insulating layer (for example, a gate insulating layer 13 (see FIG. 3)), and the insulating layer between those (for example, the gate insulating layer 13). The second sub-pixel SPb is similar to the first sub-pixel SPa. The auxiliary capacitance bus line CSb is electrically connected with a second auxiliary capacitance electrode 16eb of the second auxiliary capacitance provided to the second sub-pixel SPb. The second auxiliary capacitance is formed with the second auxiliary capacitance electrode 16eb, an expansion portion 14db of the drain lead-out wiring of the TFT 18b, which is opposed to the second auxiliary capacitance electrode 16eb across the insulating layer (for example, the gate insulating layer 13), and the insulating layer between those (for example, the gate insulating layer 13).

The auxiliary capacitance bus lines CSa and CSb may have plural pieces of auxiliary capacitance wiring. For example, as illustrated in FIG. 2, the auxiliary capacitance bus line CSa may have first auxiliary capacitance wiring 16a1, second auxiliary capacitance wiring 16a2, and auxiliary capacitance coupling wiring 16ac that electrically connects those, and the auxiliary capacitance bus line CSb may have first auxiliary capacitance wiring 16b1, second auxiliary capacitance wiring 16b2, and auxiliary capacitance coupling wiring 16bc that electrically connects those. In a case where the auxiliary capacitance bus line has plural pieces of auxiliary capacitance wiring, the liquid crystal display panel may be caused to act without correction and without a problem even in a case where disconnection occurs to any piece of the auxiliary capacitance wiring. Further, in a case where the auxiliary capacitance bus line has plural pieces of auxiliary capacitance wiring and short-circuit occurs between the auxiliary capacitance wiring and the source bus line, a short-circuited portion of the auxiliary capacitance wiring is cut in order to make the portion electrically independent from the auxiliary capacitance wiring, and correction may thereby be performed. Cutting of the auxiliary capacitance wiring is performed by irradiating the auxiliary capacitance wiring with laser light by using a known laser repairing device, for example.

The vertical auxiliary capacitance trunk lines 17 and the auxiliary capacitance bus lines CSa and CSb are electrically connected in CS contact portions 17c. In FIG. 2, the CS contact portion 17c is formed between the vertical auxiliary capacitance trunk line 17 and the first auxiliary capacitance wiring 16a1 provided to the auxiliary capacitance bus line CSa. However, embodiments are not limited to this, but the CS contact portion 17c may be formed between the vertical auxiliary capacitance trunk line 17 and the second auxiliary capacitance wiring 16a2 provided to the auxiliary capacitance bus line CSa. The same applies to the auxiliary capacitance bus line CSb. A structure of the CS contact portion 17c will be described with reference to FIG. 3. FIG. 3 is one example of a schematic cross-sectional diagram of the TFT substrate 10A along line 3A-3A′ in FIG. 2.

The TFT substrate 10A has a substrate (for example, a glass substrate) 9, a gate metal layer that is supported by the substrate 9, the gate insulating layer 13 that is formed on the gate metal layer, and a source metal layer that is formed on the gate insulating layer 13. The vertical auxiliary capacitance trunk line 17 is formed with the source metal layer, for example. The source metal layer is a layer that contains electrodes, wiring, terminals, and so forth which are formed by patterning a conductive film which forms the source electrode, the drain electrode, and the source bus lines 14a and 14b. The source metal layer includes the source electrode, the drain electrode, the source bus lines 14a and 14b, and the drain lead-out wiring (including the expansion portions 14da and 14db). The gate metal layer is a layer that contains electrodes, wiring, terminals, and so forth which are formed by patterning a conductive film which forms the gate electrode and the gate bus line 12. The gate metal layer includes the gate electrode, the gate bus line 12, the auxiliary capacitance bus lines CSa and CSb, and the first and second auxiliary capacitance electrodes 16ea and 16eb. The structure of the auxiliary capacitance is not limited to the exemplified structure, but a known structure may be used.

The TFT substrate 10A further has an interlayer insulating film 15 that covers the source metal layer 14 and a transparent conductive film (for example, ITO) 19 that is formed on the interlayer insulating film 15. The pixel electrode (the first sub-pixel electrode 11a and the second sub-pixel electrode 11b) is formed of the transparent conductive film 19. The CS contact portion 17c illustrated in FIG. 3 is formed as follows, for example. The interlayer insulating film 15 is formed on a whole surface of the substrate 9, and a contact hole is thereafter formed on the interlayer insulating film 15 such that the vertical auxiliary capacitance trunk line 17 and the auxiliary capacitance bus line CSa (first auxiliary capacitance wiring 16a1) are exposed. Next, the transparent conductive film 19 is formed by depositing a conductive material on the whole surface of the substrate 9, and patterning is thereafter performed so as to form the pixel electrode and the CS contact portion 17c.

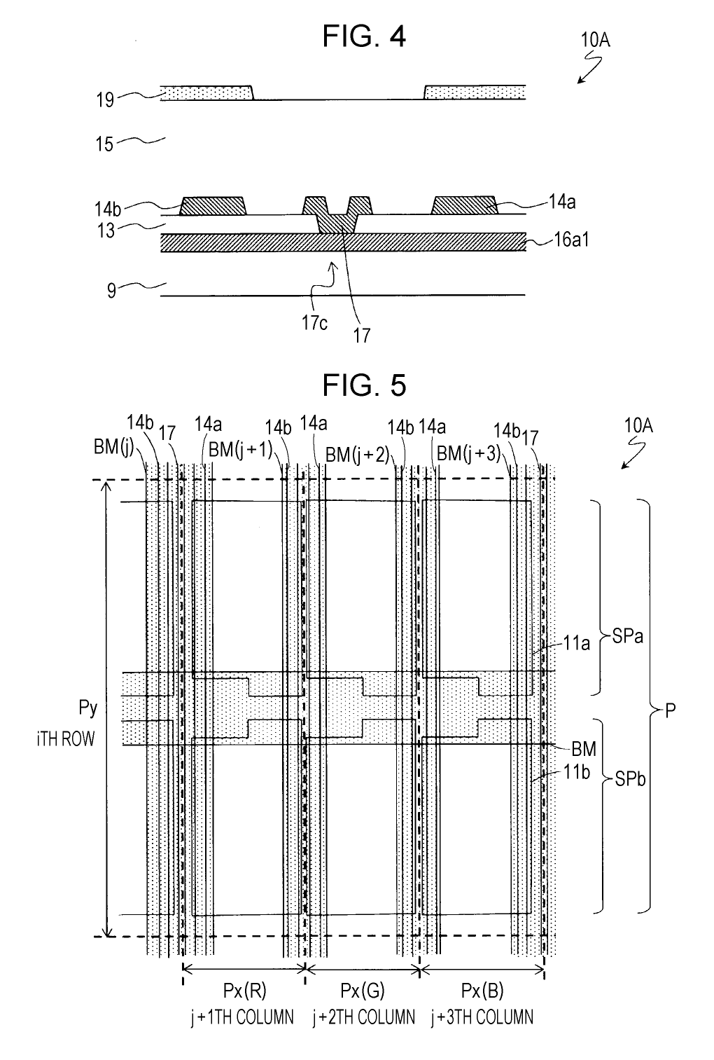

The structure of the CS contact portion 17c is not limited to the exemplified structure in FIG. 3. The CS contact portion 17c may have a structure illustrated in FIG. 4, for example. FIG. 4 is another example of the schematic cross-sectional diagram of the TFT substrate 10A along line 3A-3A′ in FIG. 2.

A lamination structure illustrated in FIG. 4 is the same as a lamination structure illustrated in FIG. 3. In the CS contact portion 17c illustrated in FIG. 4, the vertical auxiliary capacitance trunk line 17 directly contacts with the auxiliary capacitance bus line CSa (first auxiliary capacitance wiring 16a1). The CS contact portion 17c in FIG. 4 is formed by providing the contact hole in the gate insulating layer 13. In a case where a mask for providing the contact hole in the gate insulting layer 13 is newly prepared in order to form the CS contact portion 17c in FIG. 4, the number of masks may increase. However, because the CS contact portion 17c in FIG. 4 causes the vertical auxiliary capacitance trunk line 17 to directly contact with the auxiliary capacitance bus line CSa (first auxiliary capacitance wiring 16a1), an advantage of diminishing the area that is requested for forming a contact may be provided.

The aperture ratio of the pixel will be described with reference to FIG. 5. FIG. 5 is a schematic plan diagram for explaining the pixel region and the aperture ratio of the pixel of the TFT substrate 10A (see FIG. 2). In FIG. 5, for easiness of viewing, the pixel electrodes 11a and 11b, the source bus lines 14a and 14b, the vertical auxiliary capacitance trunk lines 17, and a black matrix BM are depicted, but the other configuration elements are omitted.

As illustrated in FIG. 5, the liquid crystal display panel 100A further has the black matrix BM that has plural light shielding columns arranged to perform light shielding among plural pixels, for example. The width of the light shielding column may be mutually different between the first display region 21a and the second display region 21b. For example, the plural light shielding columns, which are arranged in at least one first display region 21a, among the plural light shielding columns, include the light shielding columns with a larger width than the plural light shielding columns, which are arranged in at least one second display region 21b.

In the liquid crystal display panel 100A, the aperture ratio may be mutually different between the pixels included in the first display region 21a and the pixels included in the second display region 21b. For example, the plural pixels included in at least one first display region 21a include pixels with a lower aperture ratio than the plural pixels included in at least one second display region 21b.

The black matrix BM is provided so as to perform light shielding among the plural pixels that are provided like a matrix. The black matrix BM is like a lattice, for example, and has plural light shielding rows and plural light shielding columns.

The light shielding column is provided between adjacent pixel columns, for example. The light shielding column overlaps with the source bus lines 14a and 14b, for example. In a case where the vertical auxiliary capacitance trunk line 17 is provided between the adjacent pixel columns, the light shielding column overlaps with the source bus lines 14a and 14b and the vertical auxiliary capacitance trunk line 17.

The light shielding row is provided between adjacent pixel rows (plural pixels that are disposed along the row direction), for example. The light shielding row may also be provided between adjacent sub-pixels in the column direction, for example. The light shielding row overlaps with the gate bus line 12, for example.

The black matrix BM is provided in the counter substrate, for example. The black matrix BM may be formed in the same layer as a color filter layer, for example.

In FIG. 5, the color display pixel of the liquid crystal display panel 100A is configured with the R pixel, the G pixel, and the B pixel of three colors and displays a different color in each pixel column. For example, the pixel of the (j+1)th column is the R pixel, the pixel of the (j+2)th column is the G pixel, and the pixel of the (j+3)th column is the B pixel. The light shielding column that is provided between the pixel of the (j+1)th column and the pixel of the (j+2)th column is expressed as BM(j+1). In the first display region 21a of the liquid crystal display panel 100A, the vertical auxiliary capacitance trunk line 17 is provided between an R pixel column and a B pixel column, but the vertical auxiliary capacitance trunk line 17 is not provided between a G pixel column and the B pixel column or between the R pixel column and the G pixel column. In the first display region 21a, the width of a light shielding column BM(j) is larger than the widths of light shielding columns BM(j+1) and BM(j+2). In this case, in the first display region 21a, the aperture ratios of the R pixel and the B pixel are lower than the aperture ratio of the G pixel.

Herein, the aperture ratio of the pixel is the ratio of the area of the portion, in which the region which has electrodes, wiring, terminals, and so forth included in the layer (for example, the metal layer) formed of the black matrix and a light shielding material are removed from the pixel region, to the area of the pixel region (the value resulting from division of the area of the whole display region by the number of pixels). The pixel region is set as the region that is surrounded by broken lines in FIG. 5. As illustrated in the drawing, a length Px(R) of the pixel region of the (j+1)th column in the row direction is set as the distance from the center line between the source bus line 14b provided on the right side of the pixel of the (j)th column and the source bus line 14a provided on the left side of the pixel of the (j+1)th column to the center line between the source bus line 14b provided on the right side of the pixel of the (j+1)th column and the source bus line 14a provided on the left side of the pixel of the (j+2)th column. In the example illustrated in FIG. 5, because the vertical auxiliary capacitance trunk line 17 is provided between the R pixel and the B pixel, the length Px(R) of the pixel region of the R pixel in the row direction and a length Px(B) of the pixel region of the B pixel in the row direction are longer than a length Px(G) of the pixel region of the G pixel in the row direction. Because a length Py of the pixel region in the column direction is common to the R pixel, the G pixel, and the B pixel, the area of the pixel region of the R pixel and the area of the pixel region of the B pixel are larger than the area of the pixel region of the G pixel. The positions of the source bus lines 14a and 14b with respect to the pixel electrodes 11a and 11b are common to the R pixel column, the G pixel column, and the B pixel column. Further, also as for the gate electrode, the gate bus line 12, the auxiliary capacitance bus lines CSa and CSb, and the first and second auxiliary capacitance electrodes 16ea and 16eb, which are included in the gate metal layer, the positions with respect to the pixel electrodes 11a and 11b are common to the R pixel column, the G pixel column, and the B pixel column (see FIG. 2). Consequently, the area of the portion in which the black matrix BM, the source metal layer, and the gate metal layer are removed from the pixel region are common to the R pixel, the G pixel, and the B pixel. In the example illustrated in FIG. 5, in the first display region 21a, the aperture ratio of the R pixel and the aperture ratio of the B pixel are lower than the aperture ratio of the G pixel.

Regardless of the color that is displayed by the pixel, the pixel included in the second display region 21b in which the vertical auxiliary capacitance trunk line 17 is not provided is the same as the pixel, in which the vertical auxiliary capacitance trunk line 17 is not provided in the pixel region, among the pixels included in the first display region 21a, for example. The pixel included in the second display region 21b is the same as the G pixel included in the first display region 21a, which is described above with reference to FIG. 5, for example. The light shielding column that is arranged in the second display region 21b is the same as BM(j+1) and BM(j+2), which are described above with reference to FIG. 5, for example, and has a smaller width than BM(j). The plural light shielding columns, which are arranged in at least one first display region 21a, among the plural light shielding columns may include the light shielding columns with a larger width than the plural light shielding columns, which are arranged in at least one second display region 21b.

Regardless of the color that is displayed by the pixel, the aperture ratio of the pixel included in the second display region 21b is the same as the aperture ratio of the pixel, in which the vertical auxiliary capacitance trunk line 17 is not provided in the pixel region, among the pixels included in the first display region 21a, for example. The aperture ratio of the pixel included in the second display region 21b is the same as the aperture ratio of the G pixel included in the first display region 21a, which is described above with reference to FIG. 5, for example. The plural pixels included in at least one first display region 21a may include the pixels with a lower aperture ratio than the plural pixels included in at least one second display region 21b.

An auxiliary capacitance trunk line that is provided in a display region of a liquid crystal display panel disclosed in FIGS. 26 to 29 of above PTL 2, for example, is arranged to overlap with pixel electrodes. PTL 2 discloses that in order to reduce an influence of a capacitance formed between the auxiliary capacitance trunk line and the pixel electrodes, two auxiliary capacitance trunk lines are arranged for one pixel column, and voltages with mutually different polarities are supplied. In this case, the aperture ratio of the pixel may be lowered. In this embodiment, as illustrated in FIG. 2 and FIG. 5, because the vertical auxiliary capacitance trunk line 17 is arranged so as not to overlap with the pixel electrodes 11a and 11b, an influence of the capacitance formed between the pixel electrodes 11a and 11b and the vertical auxiliary capacitance trunk line 17 hardly have to be taken into consideration. Consequently, because two vertical auxiliary capacitance trunk lines 17 do not have to be provided for one pixel column, a high aperture ratio may be obtained.

As described above, the first display region 21a and the second display region 21b may include the pixels with different aperture ratios. In order to reduce the difference in the transmittance between the first display region 21a and the second display region 21b, the luminances of backlights (for example, LED backlights) may be made different. The luminance of the backlight provided for the first display region 21a may be made higher than the luminance of the backlight provided for the second display region 21b. That is, a liquid crystal display device according to an embodiment of the present invention includes the liquid crystal display panel 100A and a backlight unit that emits light toward the liquid crystal display panel 100A, and the backlight unit has plural light sources. The LED backlight has plural LED light sources, and the plural LED light sources are arranged like a matrix under a display panel, for example. As for the plural LED light sources, the intensity of emitted light is controlled for each of the LED light sources or each group of the LED light sources that corresponds to an area that is in advance decided. The backlight that may change the luminance for each of the LED light sources or each of the areas in such a manner may be referred to as active backlight. Further, control of the backlight in such a manner may be referred to as area active control. For example, the plural light sources include at least one first light source that is arranged correspondingly to at least one first display region 21a and at least one second light source that is arranged correspondingly to at least one second display region 21b. In one gray scale, the at least one first light source may include the first light source that emits light with higher intensity than the intensity of light which is emitted by the at least one second light source in the one gray scale. The backlight unit may be of a direct type or may be an edge light type. A direct type backlight unit further has a diffuser plate (optical sheet) between the plural light sources and the liquid crystal display panel, for example. Light is incident on the diffuser plate from the light source that is arranged in the plane-normal direction of the diffuser plate, and the light functions as a plane light source. An edge light type backlight unit further has a light guide plate, for example, and light that is incident on the light guide plate from the light source that is arranged in an in-plane direction of the light guide plate functions as a plane light source.

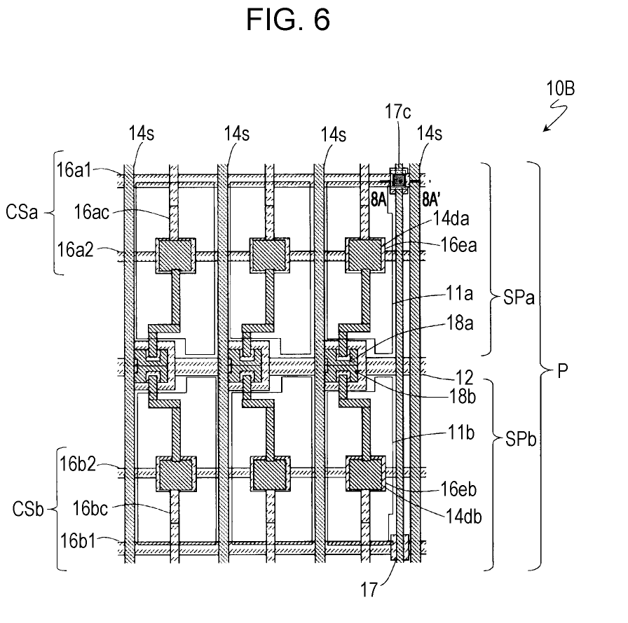

In the above, the liquid crystal display panel of this embodiment is described while the liquid crystal display panel that has the double source structure is exemplified. However, the liquid crystal display panel of this embodiment may be applied to a liquid crystal display panel that has a single source structure as illustrated in FIG. 6, for example.

FIG. 6 is a plan diagram that schematically illustrates a TFT substrate 10B which is used for the liquid crystal display panel of this embodiment. The TFT substrate 10B illustrated in FIG. 6 is used instead of the TFT substrate 10A illustrated in FIG. 2, and the liquid crystal display panel that has the single source structure may thereby be obtained.

The TFT substrate 10B has the single source structure. The TFT substrate 10A illustrated in FIG. 2 has the two source bus lines 14a and 14b for each of the pixel columns. Meanwhile, the TFT substrate 10B illustrated in FIG. 6 has only one source bus line 14s for each of the pixel columns. As it is clear from the comparison between FIG. 6 and FIG. 2, the other configurations of the TFT substrate 10B are substantially the same as the TFT substrate 10A.

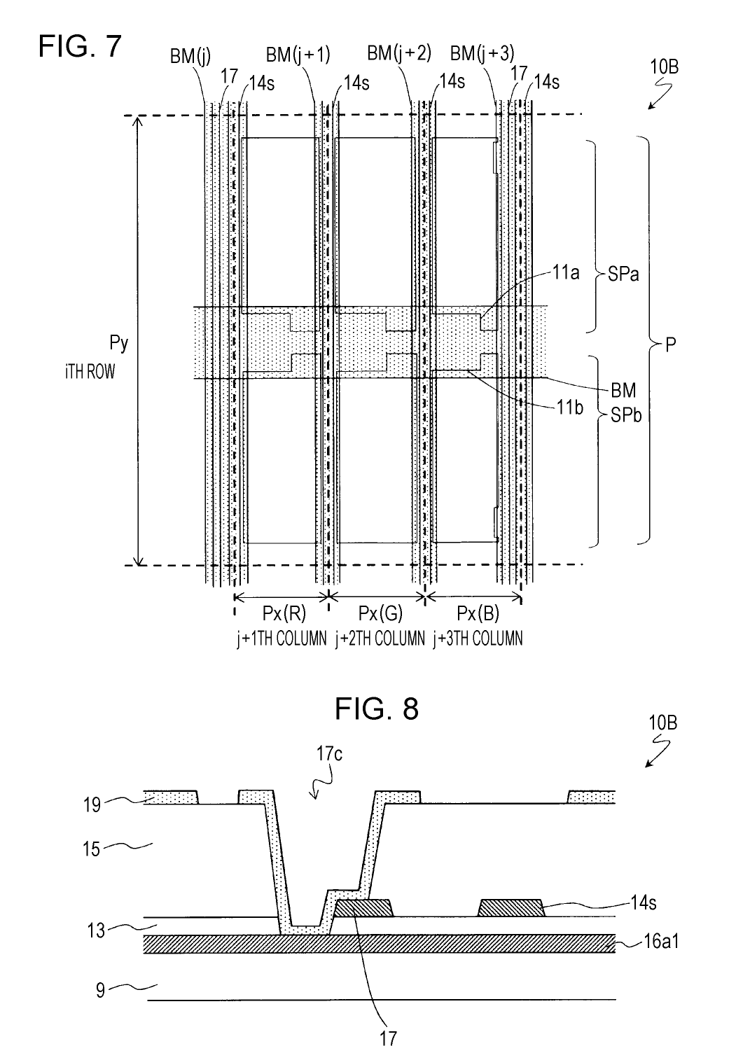

The aperture ratio of the pixel will be described with reference to FIG. 7. FIG. 7 is a schematic plan diagram for explaining the pixel region and the aperture ratio of the pixel of the TFT substrate 10B (see FIG. 6). In FIG. 7, for easiness of viewing, the pixel electrodes 11a and 11b, the source bus lines 14s, the vertical auxiliary capacitance trunk lines 17, and the black matrix BM are depicted, but the other configuration elements are omitted.

As illustrated in FIG. 7, in the first display region 21a of the liquid crystal display panel that uses the TFT substrate 10B, the vertical auxiliary capacitance trunk line 17 is provided for the B pixel column, but the vertical auxiliary capacitance trunk line 17 is not provided for the R pixel column or the G pixel column. In the first display region 21a, the width of the light shielding column BM(j) is larger than the widths of the light shielding columns BM(j+1) and BM(j+2). In the first display region 21a, the aperture ratio of the B pixel is lower than the aperture ratios of the R pixel and the G pixel.

In FIG. 7, the pixel region is indicated by broken lines, similarly to FIG. 5. In FIG. 7, as illustrated therein, the length Px(R) of the pixel region of the (j+1)th column in the row direction is set as the distance between the center lines of the source bus lines 14s that are provided at both ends of the pixels of the (j)th column. That is, the length Px of the pixel region in the row direction is common to the R pixel, the G pixel, and the B pixel (Px(R)=Px(G)=Px(B)). Because the length Py of the pixel region in the column direction is common to the R pixel, the G pixel, and the B pixel, the areas of the pixel regions of the R pixel, the G pixel, and the B pixel are the same. In the example illustrated in FIG. 7, the vertical auxiliary capacitance trunk line 17 is provided for the B pixel column. The pixel electrodes 11a and 11b of the B pixel are provided so as not to overlap with the vertical auxiliary capacitance trunk line 17. In the example illustrated in FIG. 7, in the first display region 21a, the pixel electrodes 11a and 11b of the B pixel have smaller areas than the pixel electrodes 11a and 11b of the R pixel and the G pixel. The aperture ratio of the B pixel is lower than the aperture ratios of the R pixel and the G pixel.

Regardless of the color that is displayed by the pixel, the pixel included in the second display region 21b in which the vertical auxiliary capacitance trunk line 17 is not provided is the same as the pixel, in which the vertical auxiliary capacitance trunk line 17 is not provided in the pixel region, among the pixels included in the first display region 21a, for example. The pixel included in the second display region 21b is the same as the R pixel or the G pixel included in the first display region 21a, which is described above with reference to FIG. 7, for example. The light shielding column that is arranged in the second display region 21b is the same as BM(j+1) and BM(j+2), which is described above with reference to FIG. 7, for example, and has a smaller width than BM(j). The plural light shielding columns, which are arranged in at least one first display region 21a, among the plural light shielding columns may include the light shielding columns with a larger width than the plural light shielding columns, which are arranged in at least one second display region 21b.

Regardless of the color that is displayed by the pixel, the aperture ratio of the pixel included in the second display region 21b is the same as the aperture ratio of the pixel, in which the vertical auxiliary capacitance trunk line 17 is not provided in the pixel region, among the pixels included in the first display region 21a, for example. The aperture ratio of the pixel included in the second display region 21b is the same as the aperture ratio of the R pixel or the G pixel included in the first display region 21a, which is described above with reference to FIG. 7, for example. The plural pixels included in at least one first display region 21a may include the pixels with a lower aperture ratio than the plural pixels included in at least one second display region 21b.

As exemplified in FIG. 5 and FIG. 7, the aperture ratio of the pixel that displays a certain color among the pixels included in the first display region 21a may be lower than the aperture ratios of the pixels that display the other colors. In general, even in a case where the pixel that displays a color with a low luminosity factor has a low aperture ratio compared to the pixel that display a color with a high luminosity factor, the low aperture ratio has a low influence on display. Consequently, the aperture ratio of the pixel that displays the color with a low luminosity factor is preferably made lower than the aperture ratio of the pixel that displays the color with a high luminosity factor. In a case where the color display pixel is configured with the R pixel, the G pixel, and the B pixel of three colors, green light has the highest luminosity factor, and the luminosity factor lowers in the order of red light and blue light. Thus, as described above with reference to FIG. 5 and FIG. 7, the aperture ratios of the blue pixel B and/or the red pixel R are preferably made lower than the aperture ratio of pixel of the green pixel G. In a case where the color display pixel is configured with the R pixel, the G pixel, the B pixel, and Y pixel (yellow) of four colors, similarly, the aperture ratios of the pixel B and/or the pixel R are preferably made lower than the aperture ratios of the pixels of the other colors. This is because blue light and red light have low luminosity factors compared to green light and yellow light.

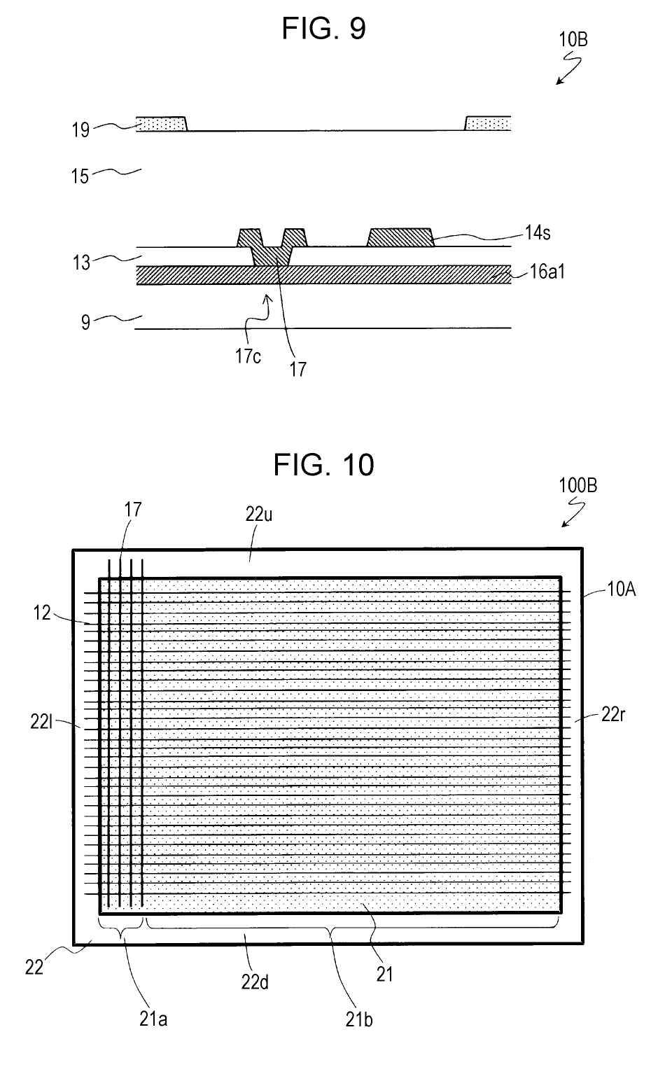

FIG. 8 and FIG. 9 are examples of a schematic cross-sectional diagram of the TFT substrate 10B along line 8A-8A′ in FIG. 6. As it is clear from the comparison between FIG. 8 and FIG. 9 and FIG. 3 and FIG. 4, the TFT substrate 10B may be the same as the TFT substrate 10A except the point that TFT substrate 10B has the single source structure.

### Second Embodiment

A liquid crystal display panel 100B according to a second embodiment of the present invention will be described with reference to FIG. 10. FIG. 10 is a schematic plan diagram of the liquid crystal display panel 100B according to the second embodiment of the present invention.

The liquid crystal display panel 100B is different from the liquid crystal display panel according to the first embodiment in a point that one first display region 21a is provided at either one end of both ends of the display region 21 in the horizontal direction. The liquid crystal display panel 100B may be the same as the liquid crystal display panel according to the first embodiment except the positions and the number of first display regions 21a.

The liquid crystal display panel 100B has the vertical auxiliary capacitance trunk lines 17 that are provided in the display region 21 and may thus achieve picture-frame narrowing. The liquid crystal display panel 100B has the vertical auxiliary capacitance trunk lines 17 only in the first display region 21a of the display region 21 but does not have the vertical auxiliary capacitance trunk lines 17 in the second display region 21b and may thus obtain a high aperture ratio. The liquid crystal display panel 100B has a narrow picture-frame and a high aperture ratio.

### Third Embodiment

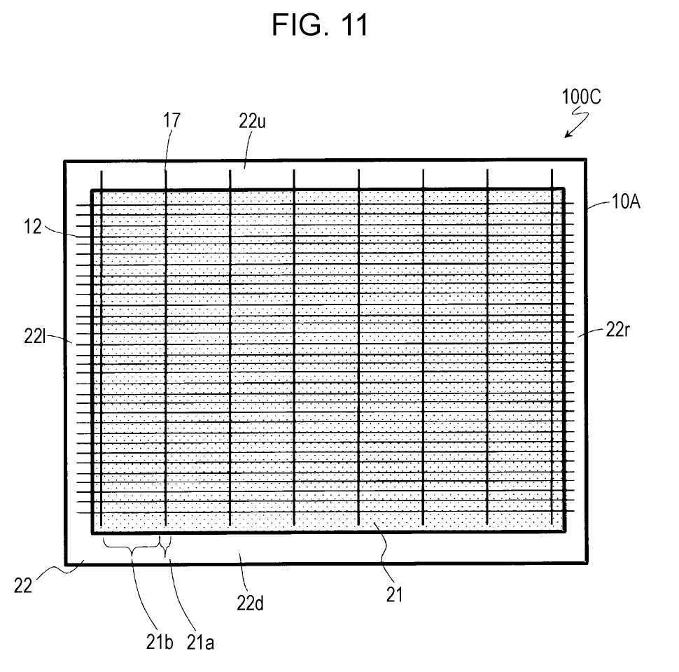

A liquid crystal display panel 100C according to a third embodiment of the present invention will be described with reference to FIG. 11. FIG. 11 is a schematic plan diagram of the liquid crystal display panel 100C according to the third embodiment of the present invention.

In the liquid crystal display panel 100C, the first display regions 21a and the second display regions 21b are alternately arrayed in the row direction (horizontal direction). For example, the first display region 21a that is configured with the pixels in 3 columns (the color display pixel in 1 column) and the second display region 21b that is configured with the pixels in 180 columns (the color display pixels in 60 columns) are alternately arrayed in the row direction. The liquid crystal display panel 100C may be the same as the liquid crystal display panel according to the first embodiment except the positions and the number of first display regions 21a.

The liquid crystal display panel 100C has the vertical auxiliary capacitance trunk lines 17 that are provided in the display region 21 and may thus achieve picture-frame narrowing. The liquid crystal display panel 100C has the vertical auxiliary capacitance trunk lines 17 only in the first display region 21a of the display region 21 but does not have the vertical auxiliary capacitance trunk lines 17 in the second display region 21b and may thus obtain a high aperture ratio. The liquid crystal display panel 100C has a narrow picture-frame and a high aperture ratio.

### Fourth Embodiment

As described above, because the first display region 21a and the second display region 21b may include the pixels with different aperture ratios, the transmittances may be different. In this embodiment, a gradation process is carried out for a boundary region of the second display region 21b, which contacts with the first display region 21a. The gradation process makes the difference in the display luminance due to the difference in the transmittance between the first display region 21a and the second display region 21b be less viewable.

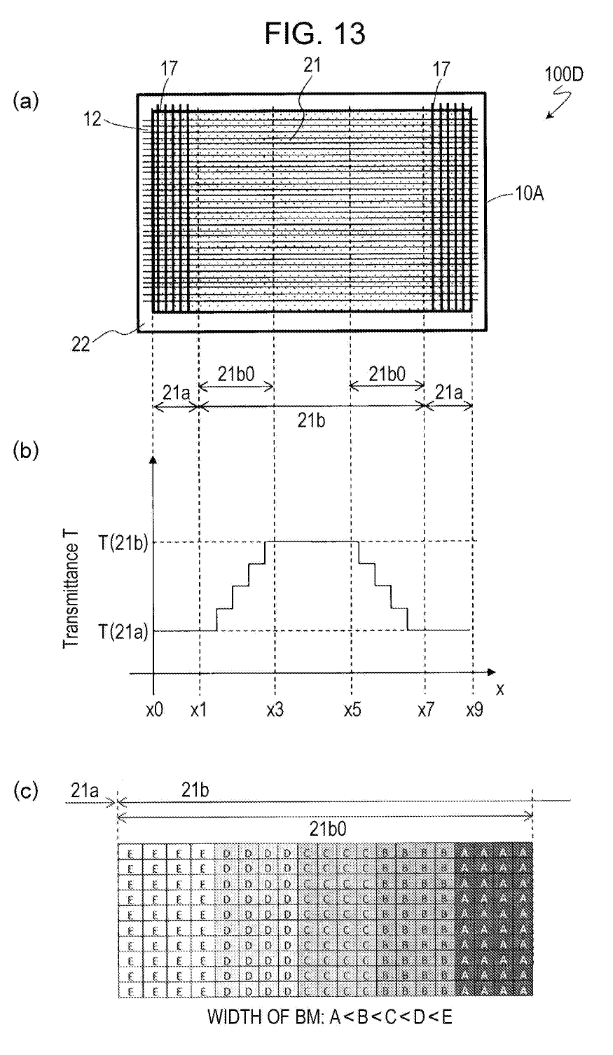

A liquid crystal display panel 100D according to a fourth embodiment of the present invention will be described with reference to FIG. 13. FIG. 13(a) is a schematic plan diagram of the liquid crystal display panel 100D according to the fourth embodiment of the present invention, FIG. 13(b) is a schematic diagram for explaining the transmittance of the display region 21 of the liquid crystal display panel 100D, and FIG. 13(c) is a diagram that schematically illustrates one example of the gradation process which is carried out for a boundary region 21b0 of the second display region 21b, which is adjacent to the first display region 21a.

As illustrated in FIG. 13(a) to FIG. 13(c), in the liquid crystal display panel 100D, the gradation process is carried out for the boundary region 21b0 of at least one second display region 21b, which is adjacent to at least one first display region 21a. The liquid crystal display panel 100D is different from the liquid crystal display panel according to the first embodiment in a point that the gradation process is carried out. The liquid crystal display panel 100D may be the same as the liquid crystal display panel according to the first embodiment except the gradation process.

The liquid crystal display panel 100D has the vertical auxiliary capacitance trunk lines 17 that are provided in the display region 21 and may thus achieve picture-frame narrowing. The liquid crystal display panel 100D has the vertical auxiliary capacitance trunk lines 17 only in the first display region 21a of the display region 21 but does not have the vertical auxiliary capacitance trunk lines 17 in the second display region 21b and may thus obtain a high aperture ratio. The liquid crystal display panel 100D has a narrow picture-frame and a high aperture ratio.

In the liquid crystal display panel 100D, because the gradation process is carried out for the region where the first display region 21a is adjacent to the second display region 21b, the difference in the display luminance due to the difference in the transmittance between the first display region 21a and the second display region 21b is less viewable. Details will be described in the following.

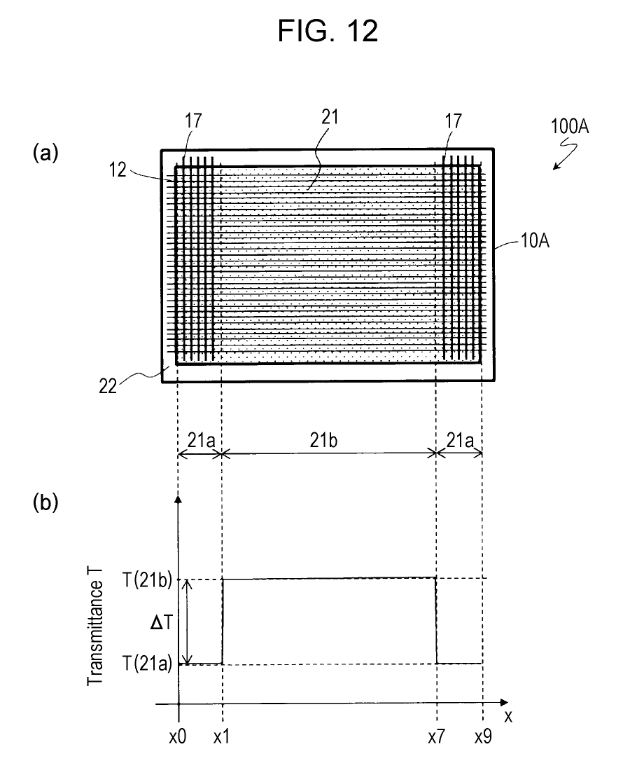

For comparison, the transmittance of the liquid crystal display panel 100A according to the first embodiment, for which the gradation process is not carried out, will be described with reference to FIG. 12. FIG. 12(a) is a schematic plan diagram of the liquid crystal display panel 100A, and FIG. 12(b) is a schematic diagram for explaining the transmittance of the display region 21 of the liquid crystal display panel 100A.

FIG. 12(b) is a graph that schematically represents the transmittance of the liquid crystal display panel 100A in FIG. 12(a). The horizontal axis represents a position x of each of the color display pixels of the liquid crystal display panel 100A in the row direction, and the vertical axis represents an average value T of the transmittances of plural pixels included in the color display pixel columns (plural color display pixels that are disposed along the column direction). The display region 21 is formed in the region of x0 to x9. In that, the two first display regions 21a are formed in the region of x0 to x1 and the region of x7 to x9, and the second display region 21b is formed in the region of x1 to x7. A transmittance T(21a) of the first display region 21a is lower than a transmittance T(21b) of the second display region 21b, and the difference between those is ΔT (=T (21b)−T(21a)). The transmittance T discontinuously changes at x1 and x7 where the first display regions 21a contact with the second display region 21b. Because the ratio of change (that is, the change ratio) in the transmittance T to the change in a position x is large, the difference in the transmittance becomes more viewable. For example, particularly in a case where gray level full screen display is performed, there is a tendency in which the difference in the transmittance is viewable. The difference in the transmittance may be viewed as the difference in the display luminance, for example. In a case where the vertical auxiliary capacitance trunk line 17 is provided only in the pixel region of the pixel that displays a specific color (for example, the B pixel), the aperture ratio is different only with the pixel that displays a specific color, and the difference in the transmittance may thus be viewed as a color shift.

Differently, as illustrated in FIG. 13(b), in the liquid crystal display panel 100D, the ratio of change in the transmittance T to the change in the position x is smaller than the liquid crystal display panel 100A. FIG. 13(b) schematically represents the transmittance of the liquid crystal display panel 100D, similarly to FIG. 12(b). In the liquid crystal display panel 100D, the boundary regions 21b0 are formed in the region of x1 to x3 and the region of x5 to x7. The gradation process is carried out for the boundary regions 21b0, the transmittance T changes from T(21a) to T(21b) while the position changes from x1 to x3, and the transmittance T changes from T(21b) to T(21a) while the position changes from x5 to x7. Consequently, the difference in the transmittance is less viewable.

In study by the present inventor, there is a tendency in which the viewability of the difference in the transmittance is more subject to the ratio of change in the transmittance to the change in the position than the absolute value ΔT of the difference in the transmittance. Consequently, in a case where the gradation process is performed in the boundary region, the ratio of change in the transmittance to the change in the position may be made lower, and the difference in the transmittance may effectively be made less viewable. The gradation process does not have to be performed for the whole display region 21, but the gradation process may be performed only for the boundary region where the first display region 21a contacts with the second display region 21b.

The gradation process may be carried out by various kinds of methods. For example, the areas of the black matrix are made different, and gradation of the transmittance may thereby be formed. In the following, examples of the gradation process will be described.

For example, the liquid crystal display panel 100D further has the black matrix that has plural light shielding columns which are arranged to perform light shielding among plural pixels. The plural light shielding columns include plural first light shielding columns that are arranged in at least one first display region 21a and plural second light shielding columns that are arranged in at least one second display region 21b.

As illustrated in FIG. 13(c), the second light shielding columns arranged in the second display region 21b include two or more kinds of light shielding columns with mutually different widths. The two or more kinds of light shielding columns are disposed such that the width of the light shielding column becomes smaller as the light shielding column is positioned farther from at least one first display region 21a. The width of each of the two or more kinds of light shielding columns may be constant in the column direction. FIG. 13(c) illustrates a disposition of the light shielding columns in the boundary region 21b0 of the second display region 21b, which is adjacent to the first display region 21a.

In the example illustrated in FIG. 13(c), five kinds of light shielding columns A, B, C, D, and E with mutually different widths are disposed. The width of the five kinds of light shielding columns is smallest with A, becomes larger in the order of B, C, and D, and is largest with E (A<B<C<D<E). In FIG. 13(c), each of rectangles in which any of the light shielding columns A to E is indicated indicates the color display pixel. The five kinds of light shielding columns are disposed such that the width of the light shielding column becomes smaller as the light shielding column is positioned farther from the first display region 21a. The width of each of the five kinds of light shielding columns is constant in the column direction.

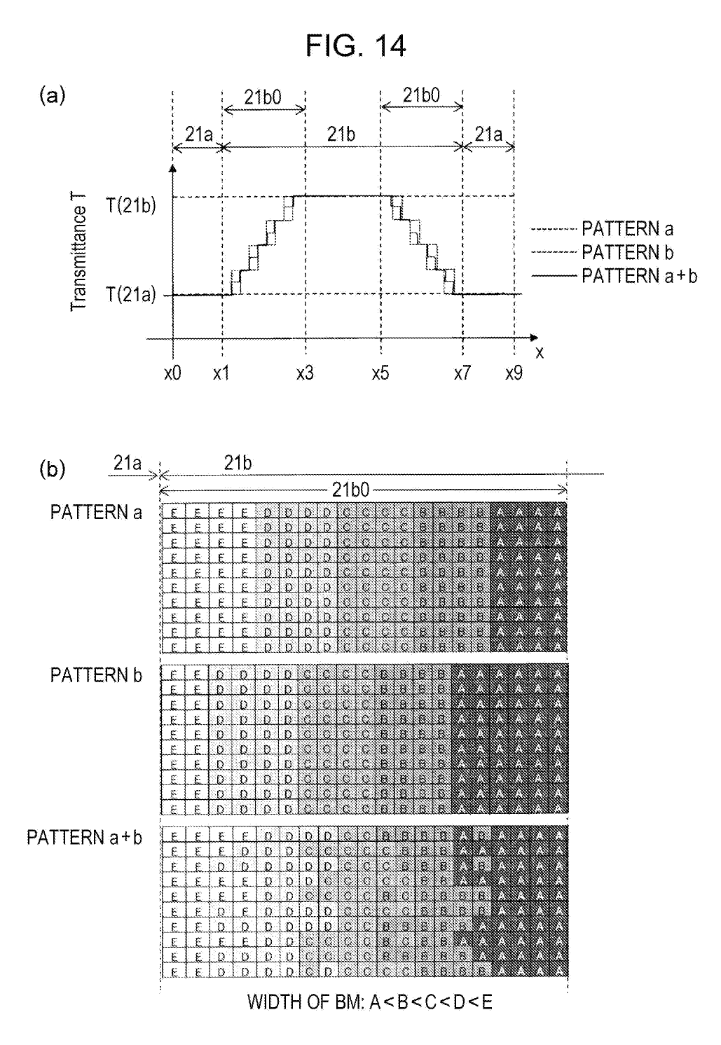

As a disposition pattern a+b of the light shielding columns, which is illustrated in FIG. 14(b), the respective widths of the two or more kinds of light shielding columns provided to the second light shielding columns arranged in the second display region 21b may not be constant in the column direction. FIG. 14(b) is a diagram that schematically illustrates the disposition pattern a+b of the light shielding columns which are formed by combining a disposition pattern a of the light shielding columns (the same as FIG. 13(c)) and a disposition pattern b of the light shielding columns. FIG. 14(a) is a schematic diagram for explaining the transmittance of the display region 21 of the liquid crystal display panel according to the fourth embodiment, for which the gradation process by the pattern a+b is carried out.

As illustrated in FIG. 14(a) and FIG. 14(b), for example, the two or more kinds of light shielding columns include the light shielding columns that have plural wide width portions and narrow width portions and are disposed such that the widths of the plural wide width portions included in the light shielding columns become smaller as the light shielding column is positioned farther from at least one first display region 21a.

As illustrated in FIG. 14(a) and FIG. 14(b), the pattern b is the arrangement in which the pattern a which is the same as FIG. 13(c) is displaced by two columns. In the pattern a+b, the color display pixels employ the kinds of light shielding columns in either one of the pattern a or the pattern b. As for the sum of the areas of the light shielding columns that are provided to plural color display pixels disposed along the column direction (which may be referred to as color display pixel column), the value for the pattern a+b is the average value of the value for the pattern a and the value for pattern b. The pattern a and the pattern b are combined together, and in the pattern a+b, the light shielding column that has plural wide width portions and plural narrow width portions is thereby formed. For example, each of the fifth column and sixth column from the right in the pattern a+b in FIG. 14(b) has the light shielding columns A (narrow width portions) and the light shielding columns B (wide width portions). For example, each of the third column and fourth column from the left in the pattern a+b in FIG. 14(b) has the light shielding columns D (narrow width portions) and the light shielding columns E (wide width portions). In such a manner, in the pattern a+b, the light shielding columns are disposed such that the width of the wide width portion becomes smaller as the light shielding column is positioned farther from the first display region 21a.

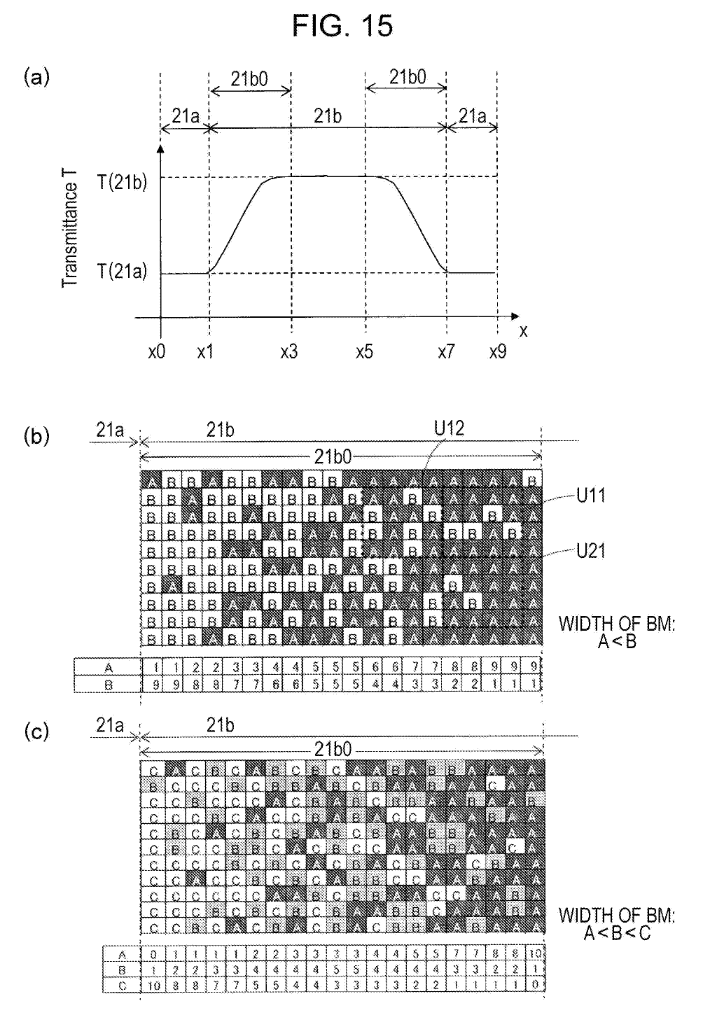

FIG. 15(a) to FIG. 15(c) illustrate another example where the respective widths of the two or more kinds of light shielding columns provided to the second light shielding columns arranged in the second display region 21b are not constant in the column direction. Each of FIG. 15(b) and FIG. 15(c) illustrates another example of the gradation process, and FIG. 15(a) is a schematic diagram for explaining the transmittance of the display region 21 of the liquid crystal display panel according to the fourth embodiment, for which the gradation process of FIG. 15(b) or FIG. 15(c) is carried out. In the liquid crystal display panels according to the fourth embodiment, for which the gradation processes of FIG. 15(b) and FIG. 15(c) are carried out, the transmittances of the display regions 21 are qualitatively the same.

As illustrated in FIG. 15(a) to FIG. 15(c), the two or more kinds of light shielding columns include the light shielding columns that have plural wide width portions and narrow width portions and are disposed such that the ratio of the plural wide width portions included in the light shielding columns becomes lower as the light shielding column is positioned farther from at least one first display region 21a.

In the example illustrated in FIG. 15(b), two kinds of light shielding columns A and B with mutually different widths are disposed. The width of the light shielding column B is larger than the width of the light shielding column A (A<B). The light shielding columns are disposed such that the ratio of the light shielding columns B (wide width portions) included in each of the color display pixel columns becomes lower as the light shielding column is positioned farther from the first display region 21a.

In the example illustrated in FIG. 15(c), three kinds of light shielding columns A, B, and C with mutually different widths are disposed. The width of the light shielding column A is smallest, and the width of the light shielding column C is largest (A<B<C). The light shielding columns are disposed such that the ratio of the light shielding columns C (wide width portions) included in each of the color display pixel columns becomes lower as the light shielding column is positioned farther from the first display region 21a. The light shielding columns are disposed such that the ratio of the light shielding columns A (narrow width portions) included in each of the color display pixel columns becomes higher as the light shielding column is positioned farther from the first display region 21a. In the example illustrated in FIG. 15(c), the light shielding columns may be disposed such that the ratio of the light shielding columns B included in each of the color display pixel columns is constant in the boundary region 21b0 or such that as illustrated in the drawing, the ratio becomes small at both ends of the boundary region 21b0 and becomes large in a central portion of the boundary region 21b0.

Here, in order to discuss a method for carrying out the gradation process, a concept of unit region will be introduced.

As described above, in a case where the gradation process is carried out, the ratio of change in the transmittance to the change in the position may be made smaller, and the difference in the transmittance may be made less viewable. The ratio of change in the transmittance to the change in the position may be provided by a color display pixel as a unit or a pixel as a unit, for example. However, embodiments are not limited to this. The unit region that is configured with plural color display pixels may be set as a minimum unit. That is, it is sufficient that the gradation process may decrease the ratio of change in the transmittance to the change in the position for the unit region as a unit.

In the liquid crystal display panel in this embodiment, the plural pixels that demarcate the display region 21 have plural unit regions that are disposed like a matrix which has rows and columns. Each of the plural unit regions includes p×q (p and q are integers of 2 or more to 1024 or less that are independent from each other) color display pixels. In the liquid crystal display panel of this embodiment, for example, plural unit regions in the boundary region 21b0 of the second display region 21b, which is adjacent to the first display region 21a, include the light shielding columns that have plural wide width portions and narrow width portions. In the unit region whose distance from at least one first display region 21a is longer, the area of the light shielding column becomes smaller. In such a liquid crystal display panel, the difference in the display luminance due to the difference in the transmittance between the first display region 21a and the second display region 21b is less viewable.

An example of the unit region is illustrated in FIG. 15(b). Each unit region U is indicated by dotted lines in FIG. 15(b). In the example in FIG. 15(b), the unit region is configured with 16 color display pixels that are disposed in 4 rows and 4 columns. In the example in FIG. 15(b), a unit region U11 is more distant from the first display region 21a than a unit region U12 that is adjacent to the unit region U11 in the row direction. The ratio of plural wide width portions (light shielding columns B) in the unit region U11 is lower than the ratio of plural wide width portions (light shielding columns B) in the unit region U12. The unit region U11 whose distance from the first display region 21a is longer has a lower ratio of plural wide width portions (light shielding columns B) and a smaller area of the light shielding columns than the unit region U12 whose distance from the first display region 21a is shorter. The size of the unit region is not limited to the exemplified size. In each of the unit regions, the number of color display pixels in the row direction may be different from the number of color display pixels in the column direction.

The arrangement of plural wide width portions and plural narrow width portions in each of the unit regions may be arbitrary. Plural wide width portions and plural narrow width portions may be disposed like a mosaic while the unit region is set as a unit. For example, in the boundary region 21b0, the arrangement of plural wide width portions and plural narrow width portions in a certain unit region may be different from the arrangement of plural wide width portions and plural narrow width portions in the adjacent unit region to the unit region in the row direction.

As exemplified in FIG. 13(c), in the boundary region 21b0, the arrangement of plural wide width portions and plural narrow width portions in a certain unit region may be the same as the arrangement of plural wide width portions and plural narrow width portions in the adjacent unit region to the unit region in the column direction.

As exemplified in FIG. 14(b) (pattern a+b), FIG. 15(b), and FIG. 15(c), in the boundary region 21b0, the arrangement of plural wide width portions and plural narrow width portions in a certain unit region may be different from the arrangement of plural wide width portions and plural narrow width portions in the adjacent unit region to the unit region in the column direction. The arrangement of plural wide width portions and plural narrow width portions in a certain unit region may be different from the arrangement of plural wide width portions and plural narrow width portions in the adjacent unit region to the unit region in the row direction and may be different from the arrangement of plural wide width portions and plural narrow width portions in the adjacent unit region to the unit region in the column direction. Plural wide width portions and plural narrow width portions may not be disposed periodically but may be disposed at random. Disposing plural wide width portions and plural narrow width portions at random means a state where each of the unit regions is configured with the color display pixels that are disposed in 10 rows and 10 columns and the arrangement of plural wide width portions and plural narrow width portions in a certain unit region is different from the arrangement of plural wide width portions and plural narrow width portions in the adjacent unit region to the unit region in the row direction and is different from the arrangement of plural wide width portions and plural narrow width portions in the adjacent unit region to the unit region in the column direction, for example.

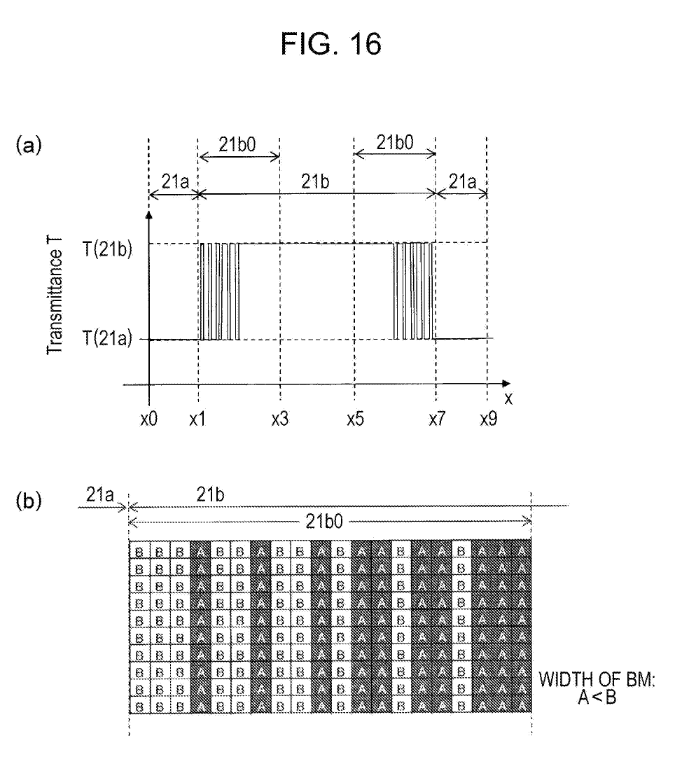

Considering the unit region as a unit, it may be understood that the difference in the transmittance may be made less viewable by the gradation processes, which are exemplified in FIG. 16(a) and FIG. 16(b). FIG. 16(b) illustrates still another example of the gradation process, and FIG. 16(a) is a schematic diagram for explaining the transmittance of the display region 21 of the liquid crystal display panel according to the fourth embodiment, for which the gradation process of FIG. 16(b) is carried out.

As illustrated in FIG. 16(b), the second light shielding columns arranged in the second display region 21b include two or more kinds of light shielding columns with mutually different widths. The two or more kinds of light shielding columns include plural wide width light shielding columns and plural narrow width light shielding columns and are disposed such that the density of the narrow width light shielding columns becomes higher as the light shielding column is positioned farther from at least one first display region 21a.

In the example illustrated in FIG. 16(b), two kinds of light shielding columns A and B with mutually different widths are disposed. The width of the light shielding column B is larger than the width of the light shielding column A (A<B). The width of each of the two kinds of light shielding columns A and B is constant in the column direction. The light shielding columns are disposed such that the ratio of the light shielding columns A (narrow width light shielding columns) becomes higher as the light shielding column is positioned farther from the first display region 21a.

Because the transmittance illustrated in FIG. 16(a) displays the respective values of the color display pixel columns, it seems that the ratio of change in the transmittance to the change in the position is not different from the liquid crystal display panel 100A illustrated in FIG. 12(b). However, considering the ratio of change in the transmittance to the change in the position while the unit region is set as a unit, the ratio of change in the transmittance of the liquid crystal display panel for which the gradation process of FIG. 16(b) is lower than the liquid crystal display panel 100A.

In a case where the unit region is set as a unit, in the boundary region 21b0, the arrangement of plural wide width portions and plural narrow width portions in a certain unit region is different from the arrangement of plural wide width portions (light shielding columns B) and plural narrow width portions (light shielding columns A) in the adjacent unit region to the unit region in the row direction and is the same as the arrangement of plural wide width portions (light shielding columns B) and plural narrow width portions (light shielding columns A) in the adjacent unit region to the unit region in the column direction.

In this embodiment, a description is made about an example where the gradation process is carried out only for the boundary region of the second display region 21b, which contacts with the first display region 21a. However, embodiments of the present invention are not limited to this. The gradation process may be carried out only for a boundary region of the first display region 21a, which contacts with the second display region 21b. The gradation process may be provided throughout the first display region 21a and the second display region 21b.

In this embodiment, a description is made on an assumption that the gradation process is carried out for the liquid crystal display panel according to the first embodiment. However, embodiments of the present invention are not limited to this. It is matter of course that the gradation process may be carried out for the liquid crystal display panel according to the second embodiment or the third embodiment.

In the liquid crystal display panel according to the third embodiment, the first display regions 21a and the second display regions 21b are alternately arrayed in the row direction (horizontal direction). In a case where the first display regions 21a and the second display regions 21b are periodically arrayed, because the transmittance observed in the unit region as a unit may be uniform in the display region 21, the difference in the transmittance may be less viewable even in a case where the gradation process is not carried out.

In the liquid crystal display panel according to an embodiment of the present invention, the arrangement of the first display regions 21a and the second display regions 21b may also include the gradation process. For example, the disposition pattern of the light shielding columns A and the light shielding columns B in the gradation process illustrated in FIG. 16(b) may be employed for the disposition pattern of the second display regions 21b and the first display regions 21a. That is, in the liquid crystal display panel according to one embodiment of the present invention, in which the first display regions 21a are provided at both ends of the display region 21 in the horizontal direction and the second display region 21b is provided in a central portion of the display region 21 in the horizontal direction, the first display regions 21a and the second display regions 21b may be provided in the boundary regions between the central portion and both of the ends and may be disposed such that in the boundary regions between the central portion and both of the ends, the density of the second display regions 21b becomes higher as the second display region 21b is positioned farther from both of the ends. Because a liquid crystal display panel in which the difference in the transmittance is less viewable may be obtained without excessively enlarging the width of the light shielding column of the black matrix, a high aperture ratio may be obtained.

### Fifth Embodiment

An embodiment of the present invention may be applied to an in-pixel gate driver monolithic (IPGDM) technology. In a liquid crystal display panel to which the IPGDM technology is applied, a TFT that configures a portion of the gate drivers (gate drive circuits) is arranged in the region of a TFT substrate, which corresponds to the display region of the liquid crystal display panel (for example, each of the pixel regions). In the liquid crystal display panel to which the IPGDM technology is applied, a portion of the gate drivers are formed in the display region, and rounding of waveform or delay of the gate signal voltage in a TFT-type liquid crystal display panel may thereby be regulated. Further, a portion of the gate drivers are formed in the display region, and picture-frame narrowing may thereby be achieved. Details about the IPGDM technology is disclosed in International Publication No. 2014/069529 Pamphlet (PTL 3) by the present applicant, for example. The entire disclosed contents of International Publication No. 2014/069529 Pamphlet will be incorporated herein by reference.

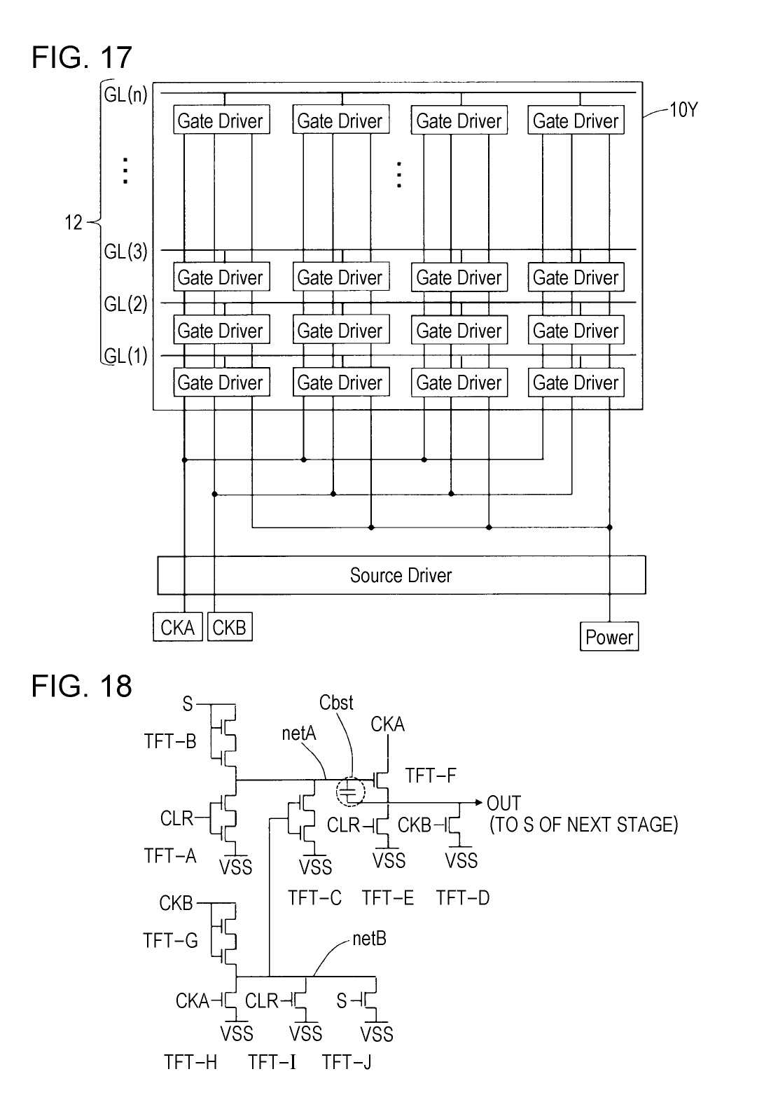

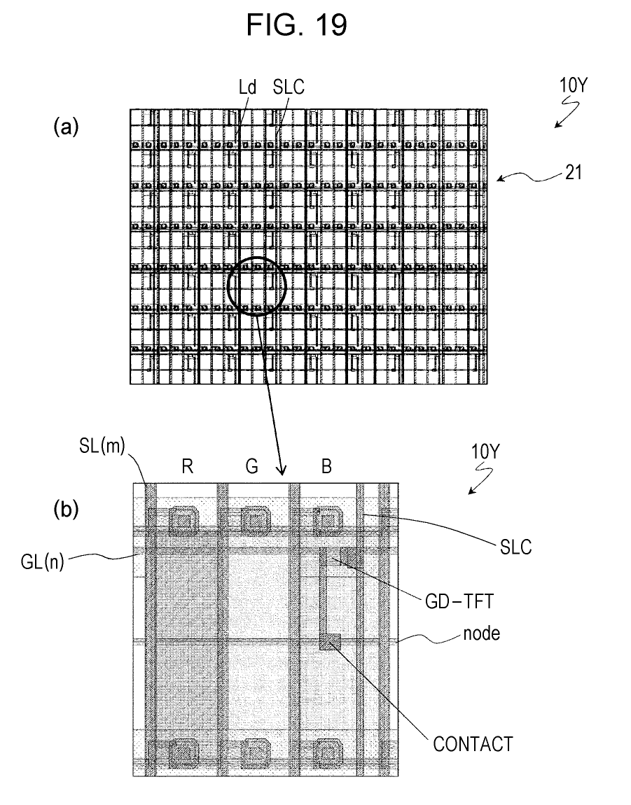

Referring to FIG. 17 to FIG. 19, a description will be made about an example of a structure of the liquid crystal display panel to which the IPGDM technology is applied. FIG. 17 is a schematic diagram that illustrates a general configuration of the liquid crystal display panel to which the IPGDM technology is applied, FIG. 18 is a diagram that illustrates an equivalent circuit of the gate driver which is formed in the display region of the liquid crystal display panel to which the IPGDM technology is applied, FIG. 19(a) is a schematic plan diagram of a TFT substrate 10Y that is used for the liquid crystal display panel to which the IPGDM technology is applied, and FIG. 19(b) is an enlarged diagram of the color display pixel of the TFT substrate 10Y.

As illustrated in FIG. 17, the gate drivers are connected with the gate bus lines 12 (GL(1), (GL(2), GL(3), and so forth) and connected with wiring to which control signals (for example, clock signals CKA and CKB) and a power source signal are supplied. As for the gate drivers formed in the display region 21, the gate driver is provided such that outputs are performed to one gate bus line 12 in two or more parts. In this case, the gate drivers that are caused to act are selected such that the load to one gate driver is equivalent. That is, only a portion of the gate drivers (for example, approximately 30%) that are formed in the display region 21 are actually driven, but the others are not driven. The gate drivers that are not driven are connected with dummy wiring.

The gate driver formed in the display region 21 is expressed by the equivalent circuit illustrated in FIG. 18. As illustrated in FIG. 18, the gate driver has 10 TFTs of TFT-A to TFT-J and one capacitor Cbst. Note that each of TFT-A, TFT-B, TFT-C, and TFT-G has two TFTs that are connected in series. In TFT-B and TFT-G among those, diode connection is performed for the two TFTs. A gate output of a previous stage is supplied to TFT-B, and a gate output S is supplied from a drain of TFT-D to TFT-B and TFT-J in a next stage. CKA and CKB in FIG. 18 are rectangular wave clock signals whose phases are reversed for one horizontal scanning period and are in a mutually reverse-phase relationship. CLR expresses a reset signal, and VSS expresses a power source voltage.

FIG. 19(a) illustrates the schematic plan diagram of the TFT substrate 10Y that is used for the liquid crystal display panel to which the IPGDM technology is applied, and FIG. 19(b) illustrates the enlarged diagram of the color display pixel of the TFT substrate 10Y. In the TFT substrate 10Y, the color display pixel is configured with the R (red) pixel, the G (green) pixel, and the B (blue) pixel of three colors, and the R pixel column, the G pixel column, and the B pixel column are disposed like stripes (that is, each of the pixel columns displays a different color). In FIG. 19(b), GL(n) expresses a gate bus line, SL(m) expresses a source bus line, and a description about connection relationships with pixel TFTs and pixel electrodes as basic configuration elements of the TFT-type liquid crystal display panel will not be made.

The gate driver formed in the display region 21 has 10 TFTs as described above. The 10 TFTs are separately formed in 10 or more pixels. In the TFT substrate 10Y, a TFT (GD-TFT) of the gate driver is formed only in the B pixel, and signal wiring SLC for GD-TFT is provided. GD-TFT corresponds to any of TFT-A to TFT-J, which are described with reference to FIG. 18, for example. The clock signal, power source voltage, and control signal are supplied to the signal wiring SLC. The length of the pixel region of the B pixel in the row direction is made longer than the lengths of the pixel regions of the R pixel and the G pixel in the row direction, the lowered amount of the aperture ratio due to provision GD-TFT and the signal wiring SLC is thereby supplemented.

In the liquid crystal display panel disclosed in above PTL 3, as illustrated in FIG. 19(a), each of the color display pixels is provided with GD-TFT and the signal wiring SLC or dummy wiring Ld for GD-TFT. Both of the signal wiring SLC and the dummy wiring Ld are wiring that extends in the column direction, and herein, those may generically be referred to as vertical bus line. In PTL 3, the dummy wiring is also referred to as adjustment wiring and is provided in a color display pixel region that does not have the signal wiring SLC in order to make the aperture ratio of each of the color display pixels substantially uniform. PTL 3 discloses that GD-TFT and the vertical bus line are arranged in such a manner, the aperture ratio of each of the color display pixels may thereby be made uniform, color unevenness, and luminance unevenness, and so forth that occur to display of each of the color display pixels may be reduced. PTL 3 discloses that GT-TFT and the vertical bus line may be arranged only in the pixel region of a specific color or may be arranged in the pixel regions of all the colors.

The above embodiments may also be applied to the liquid crystal display panel to which the IPGDM technology is applied. That is, a liquid crystal display panel according to a fifth embodiment of the present invention is different from the liquid crystal display panel according to the first embodiment in a point of being a liquid crystal display panel to which the IPGDM technology is applied. The display region of the liquid crystal display panel according to the fifth embodiment has at least one first display region in which plural vertical bus lines are formed and at least one second display region in which plural vertical bus lines are not formed. At least one second display region includes K or more contiguous pixel columns given that an integer that is greater than 1/20 of n is set as K. The liquid crystal display panel according to the fifth embodiment further has the gate drive circuit which supplies a scanning signal to plural gate bus lines, at least a portion of the gate drive circuit being formed in the display region. The plural vertical bus lines include a vertical bus line that is connected with the gate drive circuit. The plural vertical bus lines include the signal wiring SLC for GD-TFT, for example.

The liquid crystal display panel according to the fifth embodiment has the vertical bus lines that are provided in the display region and may thus achieve picture-frame narrowing. The liquid crystal display panel according to the fifth embodiment has the vertical bus lines only in the first display region of the display region but does not have the vertical bus lines in the second display region and may thus obtain a high aperture ratio. The liquid crystal display panel according to the fifth embodiment has a narrow picture-frame and a high aperture ratio.

In the liquid crystal display panel according to the fifth embodiment, the second display region may not have GD-TFT. Accordingly, the aperture ratio of the liquid crystal display panel may further be improved.

The liquid crystal display panel of this embodiment may have a multi-pixel structure. A liquid crystal display panel to which the IPGDM technology is applied and which has a multi-pixel structure is disclosed in FIG. 26 to FIG. 28 of above PTL 3, for example.

This embodiment is described as an embodiment in which the IPGDM technology is applied to the liquid crystal display panel according to the first embodiment. However, embodiments of the present invention are not limited to this. It is matter of course that the IPGDM technology may be applied to the liquid crystal display panel according to any one of the second embodiment to the fourth embodiment.

The TFT of the liquid crystal display panel according to an embodiment of the present invention may be a known TFT such as an amorphous silicon TFT (a-Si TFT), a polysilicon TFT (p-Si TFT), or a microcrystalline silicon TFT (μC-Si TFT). However, a TFT that has an oxide semiconductor layer (oxide TFT) is preferably used.

An oxide semiconductor included in the oxide semiconductor layer may be an amorphous oxide semiconductor or may be a crystalline oxide semiconductor that has a crystalline portion. As the crystalline oxide semiconductor, a polycrystalline oxide semiconductor, a microcrystalline oxide semiconductor, a crystalline oxide semiconductor in which the c-axis is substantially vertically oriented to a layer plane, and so forth may be raised.

The oxide semiconductor layer may have a lamination structure with two or more layers. In a case where the oxide semiconductor layer has the lamination structure, the oxide semiconductor layer may include an amorphous oxide semiconductor layer and a crystalline oxide semiconductor layer. Alternatively, the oxide semiconductor layer may include plural crystalline oxide semiconductor layers with different crystal structures. Alternatively, the oxide semiconductor layer may include plural amorphous oxide semiconductor layers. In a case where the oxide semiconductor layer has a two-layer structure that has an upper layer and a lower layer, the energy gap of the oxide semiconductor included in the upper layer is preferably higher than the energy gap of the oxide semiconductor included in the lower layer. However, in a case where the difference in the energy gap between those layers is comparatively small, the energy gap of the oxide semiconductor of the lower layer may be higher than the energy gap of the oxide semiconductor of the upper layer.

Materials, a structure, and a film formation method of amorphous oxide semiconductors and the above crystalline oxide semiconductors, a configuration of the oxide semiconductor layers that have lamination structures, and so forth are disclosed in Japanese Unexamined Patent Application Publication No. 2014-007399, for example. The entire disclosed contents of Japanese Unexamined Patent Application Publication No. 2014-007399 will be incorporated herein by reference.

The oxide semiconductor layer may include at least one kind of metallic element of In, Ga, and Zn, for example. The oxide semiconductor layer includes an In—Ga—Zn—O-based semiconductor (for example, indium gallium zinc oxide), for example. Here, the In—Ga—Zn—O-based semiconductor is a ternary oxide of indium (In), gallium (Ga), and zinc (Zn). The ratios (composition ratios) of In, Ga, and Zn are not particularly limited and include In:Ga:Zn=2:2:1, In:Ga:Zn=1:1:1, In:Ga:Zn=1:1:2, and so forth, for example. Such an oxide semiconductor layer may be formed of an oxide semiconductor film that includes an In—Ga—Zn—O-based semiconductor.

The In—Ga—Zn—O-based semiconductor may be amorphous or crystalline. As a crystalline In—Ga—Zn—O-based semiconductor, a crystalline In—Ga—Zn—O-based semiconductor in which the c-axis is substantially vertically oriented to a layer plane is preferable.

Note that crystal structures of crystalline In—Ga—Zn—O-based semiconductors are disclosed in Japanese Unexamined Patent Application Publication No. 2014-007399, Japanese Unexamined Patent Application Publication No. 2012-134475, Japanese Unexamined Patent Application Publication No. 2014-209727, and so forth, for example. The entire disclosed contents of Japanese Unexamined Patent Application Publication No. 2012-134475 and Japanese Unexamined Patent Application Publication No. 2014-209727 will be incorporated herein by reference. A TFT that has an In—Ga—Zn—O-based semiconductor layer has high mobility (more than 20 times compared to the a-Si TFT) and low leakage current (lower than 1/100 compared to the a-Si TFT) and is thus preferably used as a drive TFT (for example, a TFT that is included in a drive circuit that is provided around the display region including plural pixels and on the same substrate as the display region) and a pixel TFT (a TFT that is provided for a pixel).

The oxide semiconductor layer may include another oxide semiconductor instead of the In—Ga—Zn—O-based semiconductor. For example, the oxide semiconductor layer may include an In—Sn—Zn—O-based semiconductor (for example, In₂O₃—SnO₂—ZnO; InSnZnO). The In—Sn—Zn—O-based semiconductor is a ternary oxide of indium (In), tin (Sn), and zinc (Zn). Alternatively, the oxide semiconductor layer may include an In—Al—Zn—O-based semiconductor, an In—Al—Sn—Zn—O-based semiconductor, a Zn—O-based semiconductor, an In—Zn—O-based semiconductor, a Zn—Ti—O-based semiconductor, a Cd—Ge—O-based semiconductor, a Cd—Pb—O-based semiconductor, cadmium oxide (CdO), a Mg—Zn—O-based semiconductor, an In—Ga—Sn—O-based semiconductor, an In—Ga—O-based semiconductor, a Zr—In—Zn—O-based semiconductor, a Hf-In-Zn-O-based semiconductor, an Al—Ga—Zn—O-based semiconductor, a Ga—Zn—O-based semiconductor, or the like.

### INDUSTRIAL APPLICABILITY

The present invention may widely be used as a liquid crystal display panel, particularly as a large-sized liquid crystal display panel for use for a high-definition television.

### REFERENCE SIGNS LIST

10A, 10B, 10X TFT substrate
12 gate bus line
14a, 14b, 14s source bus line
CSa, CSb auxiliary capacitance bus line
17 vertical auxiliary capacitance trunk line
18a, 18b TFT
21 display region
21a first display region
21b second display region
22 picture-frame region
100A, 100B, 100C liquid crystal display panel

1. A liquid crystal display panel comprising:
a display region;
a picture-frame region around the display region;
plural pixels that are disposed in the display region like a matrix with m rows and n columns (m and n are integers of 1000 or greater which are independent from each other);
plural TFTs, each of the TFTs being connected with any of the plural pixels;
plural gate bus lines that extend in a row direction, each of the plural gate bus lines being connected with at least one of the plural TFTs;
plural source bus lines that extend in a column direction, each of the plural source bus lines being connected with at least one of the plural TFTs; and
plural vertical bus lines that extend in the column direction, wherein the display region has at least one first display region in which the plural vertical bus lines are formed and at least one second display region in which the plural vertical bus lines are not formed, and
at least one second display region includes K or more contiguous pixel columns in a case where an integer that is greater than 1/20 of n is set as K.

2. The liquid crystal display panel according to claim 1, wherein
each of the plural pixels has a first sub-pixel and a second sub-pixel that exhibit mutually different luminances at least one gray scale,
the liquid crystal display panel further includes plural auxiliary capacitance bus lines that extend in the row direction, each of the plural auxiliary capacitance bus lines being connected with an auxiliary capacitance that is provided to at least one of the first sub-pixel and the second sub-pixel which are provided to the plural pixels, and
the plural vertical bus lines are plural vertical auxiliary capacitance trunk lines that are each connected with two or more of the plural auxiliary capacitance bus lines.

3. The liquid crystal display panel according to claim 2, further comprising:
plural horizontal auxiliary capacitance trunk lines that are formed in the picture-frame region on an upper side or a lower side of the display region, wherein
each of the plural vertical auxiliary capacitance trunk lines is connected with any one of the plural horizontal auxiliary capacitance trunk lines.

4. The liquid crystal display panel according to claim 2, wherein
wiring that is electrically connected with any of the plural auxiliary capacitance bus lines is not formed in the picture-frame region of the display region in a horizontal direction.

5. The liquid crystal display panel according to claim 1, further comprising:
gate drive circuits that supply a scanning signal to the plural gate bus lines, at least a portion of the gate drive circuits being formed in the display region, wherein
the plural vertical bus lines include a vertical bus line that is connected with the gate drive circuit.

6. The liquid crystal display panel according to claim 1, wherein
the at least one first display region is two first display regions that are provided at both ends of the display region in the horizontal direction.

7. The liquid crystal display panel according to claim 1, wherein
plural pixels that are included in the at least one first display region include a pixel with a lower aperture ratio than plural pixels that are included in the at least one second display region.

8. The liquid crystal display panel according to claim 1, further comprising:
a black matrix that has plural light shielding columns which are arranged to perform light shielding among the plural pixels, wherein
plural first light shielding columns, which are arranged in the at least one first display region, among the plural light shielding columns, include a light shielding column with a larger width than plural second light shielding columns, which are arranged in the at least one second display region.

9. The liquid crystal display panel according to claim 1, wherein
a gradation process is carried out for a boundary region of the at least one second display region that is adjacent to the at least one first display region.

10. The liquid crystal display panel according to claim 9, further comprising:
a black matrix that has plural light shielding columns which are arranged to perform light shielding among the plural pixels, wherein
the plural light shielding columns include plural first light shielding columns that are arranged in the at least one first display region and plural second light shielding columns that are arranged in the at least one second display region, and
the plural second light shielding columns include two or more kinds of light shielding columns with mutually different widths.

11. The liquid crystal display panel according to claim 10, wherein
the two or more kinds of light shielding columns are disposed such that a width of the light shielding column becomes smaller as the light shielding column is positioned farther from the at least one first display region.

12. The liquid crystal display panel according to claim 10, wherein
the two or more kinds of light shielding columns include plural wide width light shielding columns and plural narrow width light shielding columns and are disposed such that a density of the narrow width light shielding columns becomes higher as the light shielding column is positioned farther from the at least one first display region.

13. The liquid crystal display panel according to claim 11, wherein
a width of each of the two or more kinds of light shielding columns is constant in the column direction.

14. The liquid crystal display panel according to claim 10, wherein
the two or more kinds of light shielding columns include light shielding columns that have plural wide width portions and plural narrow width portions and are disposed such that a ratio of the plural wide width portions that are included in the light shielding columns becomes lower as the light shielding column is positioned farther from the at least one first display region.

15. The liquid crystal display panel according to claim 10, wherein
the two or more kinds of light shielding columns include light shielding columns that have plural wide width portions and plural narrow width portions and are disposed such that the width of the plural wide width portions that are included in the light shielding columns becomes smaller as the light shielding column is positioned farther from the at least one first display region.

16. The liquid crystal display panel according to claim 9, further comprising:
a black matrix that has plural light shielding columns which are arranged to perform light shielding among the plural pixels, wherein
the plural pixels configure plural color display pixels, each of the plural color display pixels includes three pixels that display mutually different colors,
the plural pixels have plural unit regions that are disposed like a matrix with rows and columns, each of the plural unit regions includes the p×q (p and q are integers of 2 or greater to 1024 or less that are independent from each other) color display pixels, and
the plural unit regions in the boundary region include light shielding columns that have plural wide width portions and plural narrow width portions and the unit region whose distance from the at least one first display region is longer has the light shielding column with a smaller area.

17. The liquid crystal display panel according to claim 16, wherein
in the boundary region, arrangement of the plural wide width portions and the plural narrow width portions in one unit region is different from arrangement of the plural wide width portions and the plural narrow width portions in an adjacent unit region to the unit region in the row direction.

18. The liquid crystal display panel according to claim 16, wherein
in the boundary region, arrangement of the plural wide width portions and the plural narrow width portions in one unit region is the same as arrangement of the plural wide width portions and the plural narrow width portions in an adjacent unit region to the unit region in the column direction.

19. The liquid crystal display panel according to claim 16, wherein
in the boundary region, arrangement of the plural wide width portions and the plural narrow width portions in one unit region is different from arrangement of the plural wide width portions and the plural narrow width portions in an adjacent unit region to the unit region in the column direction.

20. A liquid crystal display device comprising:
the liquid crystal display panel according to claim 1; and
a backlight unit that emits light toward the liquid crystal display panel, wherein
the backlight unit has plural light sources,
the plural light sources include at least one first light source that is arranged correspondingly to the at least one first display region and at least one second light source that is arranged correspondingly to the at least one second display region, and
in one gray scale, the at least one first light source includes the first light source that emits light with higher intensity than intensity of light which is emitted by the at least one second light source in the one gray scale.
